(19) United States
(12) Patent Application Publication
(10) Pub. No.: US 2025/0087274 A1
(43) Pub. Date: Mar. 13, 2025

(54) SEMICONDUCTOR STORAGE DEVICE

(71) Applicant: Kioxia Corporation, Tokyo (JP)

(72) Inventors: Hiroyuki TAKENAKA, Kamakura Kanagawa (JP); Akihiko CHIBA, Yokohama Kanagawa (JP); Teppei HIGASHITSUJI, Fujisawa Kanagawa (JP); Kiyofumi SAKURAI, Yokohama Kanagawa (JP); Hiroaki NAKASA, Yokohama Kanagawa (JP); Youichi MAGOME, Kawasaki Kanagawa (JP)

(21) Appl. No.: 18/960,230

(22) Filed: Nov. 26, 2024

Related U.S. Application Data
(62) Division of application No. 18/480,305, filed on Oct. 3, 2023, now Pat. No. 12,183,401.
Application No. 18/480,305 is a continuation of application No. 17/458,067, filed on Aug. 26, 2021, now Pat. No. 11,810,620.

(30) Foreign Application Priority Data
Feb. 2, 2021 (JP) 2021-015362

(51) Int. Cl. G11C 16/14; G11C 5/06; G11C 16/04; G11C 16/16; G11C 16/24; G11C 16/26; G11C 16/30

(52) U.S. Cl. CPC G11C 16/14; G11C 5/06; G11C 16/0483; G11C 16/16; G11C 16/24; G11C 16/26; G11C 16/30

(57) ABSTRACT

A semiconductor storage device includes a first semiconductor substrate, a second semiconductor substrate, a first memory cell and a second memory cell provided between the first semiconductor substrate and the second semiconductor substrate, a first word line electrically connected to the first memory cell, a second word line electrically connected to the second memory cell, a first transistor that is provided on the first semiconductor substrate and electrically connected between the first word line and a first wiring through which a voltage is applied to the first word line, and a second transistor that is provided on the semiconductor substrate and electrically connected between the second word line and a second wiring through which a voltage is applied to the second word line.

### CROSS-REFERENCE TO RELATED APPLICATIONS

This application is a division of U.S. patent application Ser. No. 18/480,305, filed Oct. 3, 2023, which is a continuation of U.S. patent application Ser. No. 17/458,067, filed Aug. 26, 2021, which is based upon and claims the benefit of priority from Japanese Patent Application No. 2021-015362, filed Feb. 2, 2021, the entire contents of each of which are incorporated herein by reference.

### FIELD

Embodiments described herein relate generally to a semiconductor storage device.

### BACKGROUND

A semiconductor storage device of the related art includes a first semiconductor substrate, a second semiconductor substrate, a first memory cell and a second memory cell provided between the first semiconductor substrate and the second semiconductor substrate, a first word line connected to the first memory cell, a second word line connected to the second memory cell, a first transistor electrically connected to the first word line, and a second transistor electrically connected to the second word line.

### BRIEF DESCRIPTION OF THE DRAWINGS

FIG. 1 is a schematic block diagram illustrating a configuration of a memory system according to a first embodiment.

FIG. 2 is a side view schematically illustrating an example of the configuration of the memory system.

FIG. 3 is a plan view schematically illustrating the example of the configuration of the memory system.

FIG. 4 is a schematic block diagram illustrating an example of a configuration of a memory die.

FIG. 5 is a schematic circuit diagram illustrating a circuit configuration of a portion of the memory die.

FIG. 6 is a schematic circuit diagram illustrating a circuit configuration of another portion of the memory die.

FIG. 7 is an exploded perspective view schematically illustrating two chips of the memory die.

FIG. 8 is an exploded perspective view schematically illustrating transistors and wiring layers in the example of the configuration of the memory die.

FIG. 9 is a cross-sectional view schematically illustrating a first chip of the memory die.

FIG. 10 is an enlarged view schematically illustrating a portion of the first chip indicated by A in FIG. 9.

FIG. 11 is a bottom view schematically illustrating the first chip.

FIG. 12 is an enlarged view schematically illustrating a portion of the first chip indicated by B in FIG. 11.

FIG. 13 is an enlarged view schematically illustrating a portion of the first chip indicated by C in FIG. 11.

FIG. 14 is an enlarged view schematically illustrating a portion of the first chip indicated by D in FIG. 13.

FIG. 15 is an enlarged view schematically illustrating a portion of the first chip indicated by E in FIG. 14.

FIG. 16 is a cross-sectional view schematically illustrating a second chip of the memory die.

FIG. 17 is a cross-sectional view schematically illustrating the configuration of the memory die including the first and second chips.

FIG. 18 is a bottom view schematically illustrating a configuration of memory cell array layers in the first chip.

FIG. 19 is a bottom view schematically illustrating a configuration of a transistor layer in the first chip.

FIG. 20 is a plan view schematically illustrating a configuration of the second chip.

FIG. 21 is a bottom view schematically illustrating the transistor layer in the first chip.

FIG. 22 is a plan view schematically illustrating a partial configuration of the second chip.

FIG. 23 is a cross-sectional view schematically illustrating a semiconductor storage device according to a second embodiment.

FIG. 24 is a cross-sectional view schematically illustrating a semiconductor storage device according to a third embodiment.

FIG. 25 is a cross-sectional view schematically illustrating a semiconductor storage device according to a fourth embodiment.

FIG. 26 is a cross-sectional view schematically illustrating a semiconductor storage device according to another embodiment.

FIG. 27 is a cross-sectional view schematically illustrating a semiconductor storage device according to still another embodiment.

### DETAILED DESCRIPTION

Embodiments provide a semiconductor storage device that facilitates high density integration.

In general, according to one embodiment, a semiconductor storage device includes a first semiconductor substrate, a second semiconductor substrate, a first memory cell and a second memory cell provided between the first semiconductor substrate and the second semiconductor substrate, a first word line electrically connected to the first memory cell, a second word line electrically connected to the second memory cell, a first transistor that is provided on the first semiconductor substrate and electrically connected between the first word line and a first wiring through which a voltage is applied to the first word line, and a second transistor that is provided on the second semiconductor substrate and electrically connected between the second word line and a second wiring through which a voltage is applied to the second word line.

Then, a semiconductor storage device according to embodiments will be described in detail with reference to the drawings. The following embodiments are merely examples, and are not intended to limit the present disclosure. The following drawings are schematic, and some configurations and the like may be omitted for the sake of convenience in description. Common portions in a plurality of embodiments are denoted by the same reference signs, and repetitive description thereof may be omitted.

The term “semiconductor storage device” used in the present specification may mean a memory die, or a memory system including a controller die, such as a memory chip, a memory card, or a solid state drive (SSD). The term “semiconductor storage device” may mean a configuration that includes a host computer such as a smartphone, a tablet terminal, and a personal computer.

In the present specification, when a first component is said to be “electrically connected” to a second component, the first component may be directly connected to the second component, or the first component may be connected to the second component via a wiring, a semiconductor member, a transistor, or the like. For example, when three transistors are connected in series, the first transistor is “electrically connected” to the third transistor even though the second transistor is in an OFF state.

In the present specification, a case where the first component is said to be “connected between” the second component and the third component may mean that the first component, the second component, and the third component are connected in series and the second component is connected to the third component via the first component.

In the present specification, a case where a circuit or the like is said to “cause two wirings and the like to be electrically connected” may mean, for example, that the circuit or the like includes a transistor and the like, the transistor and the like are provided on a current path between the two wirings and the like, and the transistor and the like transition into an ON state.

In the present specification, a predetermined direction parallel to an upper surface of a semiconductor substrate is referred to as an X direction, a direction which is parallel to the upper surface of the semiconductor substrate and is perpendicular to the X direction is referred to as a Y direction, and a direction perpendicular to the upper surface of the semiconductor substrate is referred to as a Z direction.

In the present specification, a direction along a predetermined surface is referred to as a first direction, a direction intersecting the first direction along the predetermined surface is referred to as a second direction, and a direction intersecting the predetermined surface is referred to as a third direction. The first direction, the second direction, and the third direction may or may not correspond to any of the X direction, the Y direction, and the Z direction.

When expressions such as “upper” and “lower” are used in the present specification, for example, among two semiconductor substrates included in a memory die, one provided with a bonding pad electrode may be defined as the upper semiconductor substrate, and the other not provided with the bonding pad electrode may be defined as the lower semiconductor substrate. When components included in the memory die are described, for example, a direction towards the upper semiconductor substrate along the Z direction may be referred to as being upward, and a direction towards the lower semiconductor substrate along the Z direction may be referred to as being downward. A case where a lower surface and a lower end of a certain component are described may mean a surface and an end portion of the component on the lower semiconductor substrate side. A case where an upper surface and an upper end of a certain component are described may mean a surface and an end portion of the component on the upper semiconductor substrate side. A surface intersecting the X direction or the Y direction may be referred to as a side surface or the like.

### First Embodiment

### Memory System 10

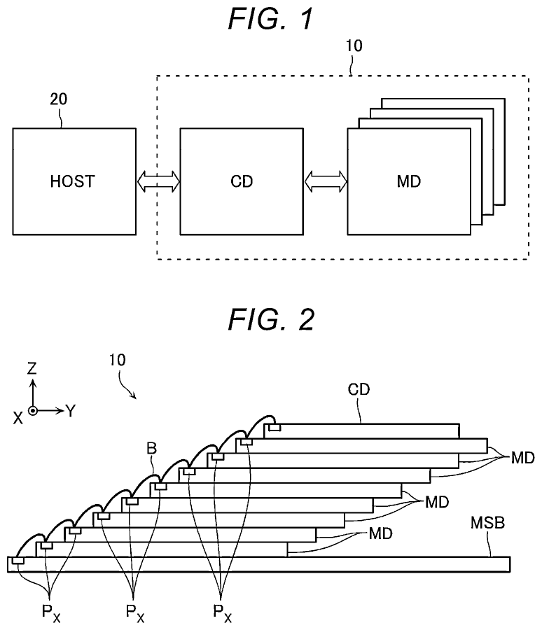

FIG. 1 is a schematic block diagram illustrating a configuration of a memory system 10 according to a first embodiment.

The memory system 10, for example, reads, writes, and erases user data in accordance with a signal transmitted from a host computer 20. The memory system 10 is, for example, a memory chip, a memory card, an SSD, or other systems capable of storing user data. The memory system 10 includes a plurality of memory dies MD and a controller die CD. The memory die MD stores user data. The controller die CD is connected to the plurality of memory dies MD and the host computer 20. The controller die CD includes a processor, and a RAM, for example. The controller die CD performs processing such as conversion between a logical address and a physical address, bit error detection/correction, garbage collection (compaction), and wear leveling.

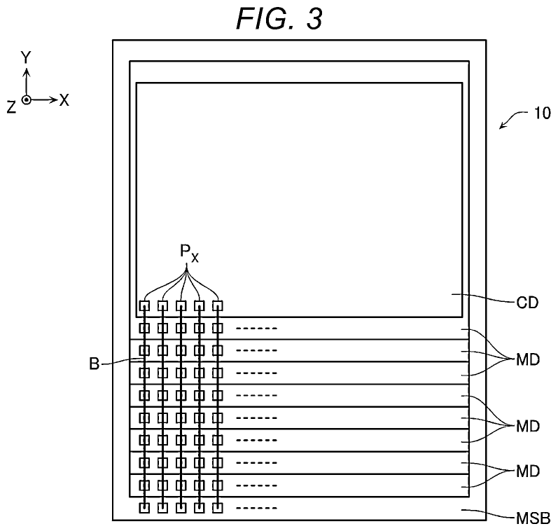

FIG. 2 is a side view schematically illustrating an example of the configuration of the memory system 10 according to the first embodiment. FIG. 3 is a plan view schematically illustrating the example of the configuration. For convenience of description, illustrations of some components are omitted in FIGS. 2 and 3.

As illustrated in FIG. 2, the memory system 10 according to the present embodiment includes a mounting substrate plurality of memory dies MD, and a controller die CD. A bonding pad electrode P_{X} is provided in a region of an end portion of the upper surface of the mounting substrate MSB in the Y direction. A region of the upper surface of the mounting substrate MSB other than the end portion in the Y direction is adhered to the lower surface of the memory die MD via an adhesive or the like. A plurality of memory dies MD is stacked on the mounting substrate MSB. A bonding pad electrode P_{X} is provided in the region of the end portion in the Y direction of the upper surface of the memory die MD. A region of the upper surface of the memory die MD other than the end portion in the Y direction is adhered to the lower surface of another memory die MD or the lower surface of the controller die CD via an adhesive or the like. The controller die CD is stacked on the memory die MD. A bonding pad electrode P_{X} is provided in a region of an end portion of the upper surface of the controller die CD in the Y direction.

As illustrated in FIG. 3, each of the mounting substrate MSB, the plurality of memory dies MD, and the controller die CD includes a plurality of bonding pad electrodes P_{X} arranged in the X direction. The plurality of bonding pad electrodes P_{X} provided on the mounting substrate MSB, the plurality of memory dies MD, and the controller die CD are connected to each other via bonding wires B.

The components illustrated in FIGS. 2 and 3 are merely an example, and the specific components may be adjusted as appropriate. For example, in the example illustrated in FIGS. 2 and 3, the controller die CD is stacked on the plurality of memory die MD. The memory die MD and the controller die CD are connected by a bonding wire B. The plurality of memory dies MD and the controller die CDs are included in one package. However, the controller die CD may be included in a package different from the memory die MD.

### Circuit Configuration of Memory Die MD

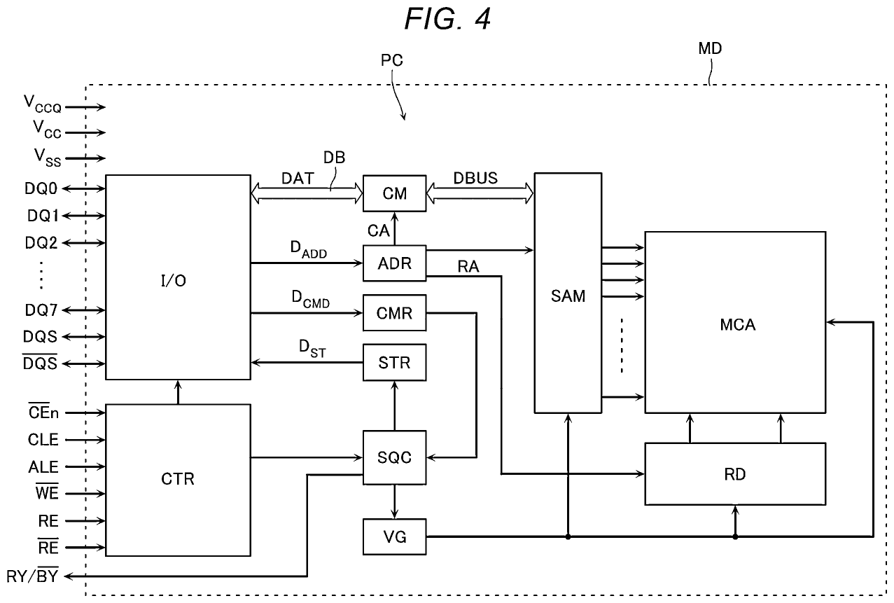

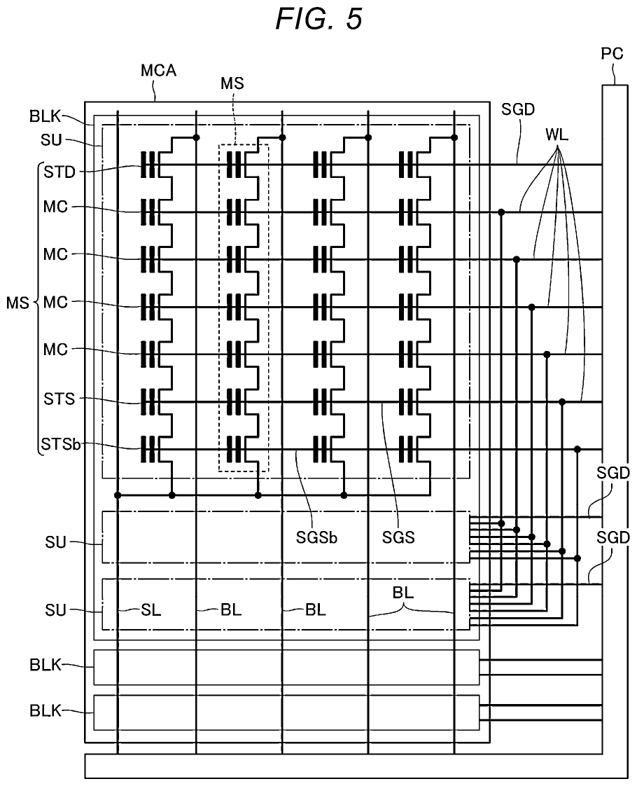

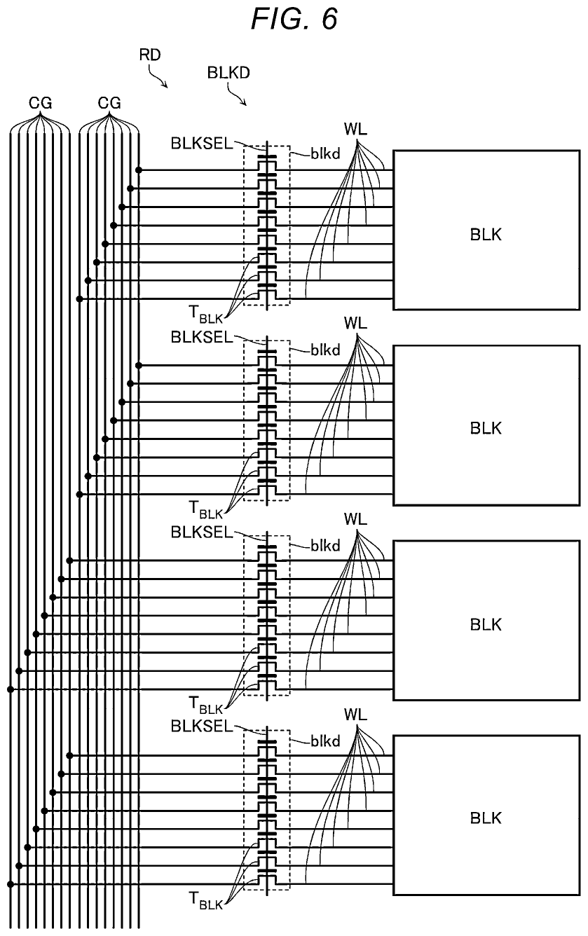

FIG. 4 is a schematic block diagram illustrating an example of the configuration of the memory die MD according to a first embodiment. FIGS. 5 and 6 are schematic circuit diagrams illustrating a partial configuration of the memory die MD.

FIG. 4 illustrates a plurality of control terminals and the like. The plurality of control terminals may be represented as control terminals corresponding to a high active signal (positive logic signal). The plurality of control terminals may be represented as control terminals corresponding to a low active signal (negative logic signal). The plurality of control terminals may be represented as control terminals corresponding to both the high active signal and the low active signal. In FIG. 4, the reference sign of the control terminal corresponding to the low active signal includes an overline. In the present specification, the reference sign of the control terminal corresponding to the low active signal includes a slash (“/”). The illustration of FIG. 4 is an example, and the specific form may be adjusted as appropriate. For example, some or all of high active signals may be set to low active signals, or some or all of low active signals may be set to high active signals.

As illustrated in FIG. 4, the memory die MD includes a memory cell array MCA and a peripheral circuit PC. The peripheral circuit PC includes a voltage generation circuit VG, a row decoder RD, a sense amplifier module SAM, and a sequencer SQC. The peripheral circuit PC further includes a cache memory C_{M}, an address register ADR, a command register CMR, and a status register STR. The peripheral circuit PC further includes an input/output control circuit I/O and a logic circuit CTR.

### Circuit Configuration of Memory Cell Array MCA

As illustrated in FIG. 5, the memory cell array MCA includes a plurality of memory blocks BLK. Each of the plurality of memory blocks BLK includes a plurality of string units SU. Each of the plurality of string units SU includes a plurality of memory strings MS. One end of each of the plurality of memory strings MS is connected to the peripheral circuit PC via a bit line BL. The other end of each of the plurality of memory strings MS is connected to the peripheral circuit PC via a common source line SL.

The memory string MS includes a drain-side select transistor STD, a plurality of memory cells (memory transistors) MC, a source-side select transistor STS, and a source-side select transistor STSb. The drain-side select transistor STD, the plurality of memory cells MC, the source-side select transistor STS, and the source-side select transistor STSb are connected in series between the bit line BL and the source line SL. The drain-side select transistor STD, the source-side select transistor STS, and the source-side select transistor STSb may be simply referred below to as select transistors (STD, STS, and STSb).

The memory cell MC is a field effect transistor. The memory cell MC includes a semiconductor layer, a gate insulating film, and a gate electrode. The semiconductor layer functions as a channel region. The gate insulating film includes a charge storage film. The threshold voltage of the memory cell MC changes depending on the charge quantity in the charge storage film. The memory cell MC stores data of one bit or a plurality of bits. A word line WL is connected to each of the gate electrodes of the plurality of memory cells MC corresponding to one memory string MS. Each word line WL is commonly connected across all memory strings MS in one memory block BLK.

The select transistors (STD, STS, and STSb) are field effect transistors. Each of the select transistors (STD, STS, and STSb) includes a semiconductor layer, a gate insulating film, and a gate electrode. The semiconductor layer functions as a channel region. Selection gate lines (SGD, SGS, and SGSb) are connected to gate electrodes of the select transistors (STD, STS, and STSb), respectively. One drain-side selection gate line SGD is commonly connected across all memory strings MS in one string unit SU. One source-side selection gate line SGS is commonly connected across all memory strings MS in one memory block BLK. One source-side selection gate line SGSb is commonly connected across all memory strings MS in one memory block BLK.

### Circuit Configuration of Voltage Generation Circuit VG

The voltage generation circuit VG (FIG. 4) includes, for example, a step-down circuit and a step-up circuit. The step-down circuit is, for example, a regulator. The step-up circuit is, for example, a charge pump circuit. Each of the step-down circuit and the step-up circuit is connected to a power-source voltage supply line. A power-source voltage V_{CC} and a ground voltage V_{SS} are supplied to the power-source voltage supply line. The power-source voltage supply line is connected to, for example, the bonding pad electrode P_{X} described with reference to FIGS. 2 and 3. The voltage generation circuit VG generates a plurality of operation voltages and simultaneously outputs the generated operation voltages to a plurality of voltage supply lines, respectively. The plurality of operation voltages are supplied to the bit line BL, the source line SL, the word line WL, and the selection gate lines (SGD, SGS, and SGSb), for example, during a read operation, a write operation, and an erasing operation on the memory cell array MCA. The operation voltage is appropriately adjusted in accordance with a control signal from the sequencer SQC.

### Circuit Configuration of Row Decoder RD

The row decoder RD includes a block decoder BLK_{D}, for example, as illustrated in FIG. 6.

The block decoder BLK_{D} includes a plurality of block decoding units blkd. The plurality of block decoding units blkd are provided respectively for the plurality of memory blocks BLK in the memory cell array MCA. The block decoding unit blkd includes a plurality of transistors T_{BLK}. The plurality of transistors T_{BLK} are provided respectively for the plurality of word lines WL in the memory block BLK. The transistor T_{BLK} is, for example, a field effect type NMOS transistor. The drain electrode of the transistor T_{BLK} is connected to the word line WL. The source electrode of the transistor T_{BLK} is connected to a wiring CG. The wiring CG is connected to a plurality of block decoding units blkd in the block decoder BLK_{D}. For example, each wiring CG may be connected to the source electrode of one transistor T_{BLK} in all the block decoding units blkd in the block decoder BLK_{D}. The gate electrode of the transistor T_{BLK} is connected to a signal supply line BLKSEL. A plurality of signal supply lines BLKSEL are provided respectively for the block decoding units blkd. The signal supply line BLKSEL is connected to all the transistors T_{BLK} in the block decoding unit blkd.

In a read operation, a write operation, and the like, for example, one signal supply line BLKSEL corresponding to a row address RA included in address data D_{ADD} stored in the address register ADR (FIG. 4) is in an “H” state, and other signal supply lines BLKSEL are in an “L” state. For example, a predetermined drive voltage having a positive magnitude is supplied to the one signal supply line BLKSEL, and a ground voltage V_{SS} or the like is supplied to other signal supply lines BLKSEL. Thus, all the word lines WL in one memory block BLK corresponding to the row address RA are electrically connected respectively to all the wirings CG. In addition, all the word lines WL in the other memory blocks BLK are in a floating state.

The row decoder RD further includes a decoding circuit (not illustrated) and a switch circuit (not illustrated).

For example, the decoding circuit (not illustrated) sequentially decodes the row address RA in accordance with the control signal from the sequencer SQC (FIG. 4), selectively sets one of the plurality of signal supply lines BLKSEL to be in the “H” state, and sets others to be in the “L” state. The switch circuit supplies a plurality of voltages output from the voltage generation circuit VG to the desired wiring CG in accordance with output signals of the decoding circuit and the sequencer SQC.

### Circuit Configuration of Sense Amplifier Module SAM

The sense amplifier module SAM (FIG. 4) includes, for example, a plurality of sense amplifiers. The sense amplifier includes a sense transistor, a data wiring, a latch circuit, and a voltage transfer circuit. The gate electrode of the sense transistor is connected to the bit line BL. The drain electrode of the sense transistor is connected to the data wiring. The sense transistor transitions into the ON state in accordance with the voltage or the current of the bit line BL. The data wiring is charged or discharged in accordance with the ON/OFF state of the sense transistor. The latch circuit latches data of “1” or “0” in accordance with the voltage of the data wiring. The voltage transfer circuit causes the bit line BL to be electrically connected to one of the two voltage supply lines in accordance with the data latched by the latch circuit.

### Circuit Configuration of Cache Memory C_{M}

The cache memory C_{M} (FIG. 4) includes a plurality of latch circuits. The plurality of latch circuits are connected to the latch circuit in the sense amplifier module SAM via a wiring DBUS. Pieces of data DAT included in the plurality of latch circuits sequentially transferred to the sense amplifier module SAM or the input/output control circuit I/O.

A decoding circuit (not illustrated) and a switch circuit (not illustrated) are connected to the cache memory C_{M}. The decoding circuit decodes a column address CA included in the address data D_{ADD} stored in the address register ADR (FIG. 4). The switch circuit causes the latch circuit corresponding to the column address CA to be electrically connected to a bus DB in accordance with the output signal of the decoding circuit.

### Circuit Configuration of Sequencer SQC

The sequencer SQC (FIG. 4) outputs an internal control signal to the row decoder RD, the sense amplifier module SAM, and the voltage generation circuit VG in accordance with command data D_{CMD} stored in the command register CMR. The sequencer SQC outputs status data D_{ST} indicating the state of the sequencer itself to the status register STR as appropriate.

The sequencer SQC generates a ready/busy signal and outputs the generated ready/busy signal to a terminal RY//BY. During a period (busy period) in which the terminal RY//BY is in the “L” state, an access to the memory die MD is basically prohibited. During a period (ready period) in which the terminal RY//BY is in the “H” state, the access to the memory die MD is permitted. The terminal RY//BY is implemented, for example, by the bonding pad electrode P_{X} described with reference to FIGS. 2 and 3.

### Circuit Configuration of Input/Output Control Circuit I/O

The input/output control circuit I/O includes data signal input/output terminals DQ0 to DQ7, toggle signal input/output terminals DQS/DQS, a plurality of input circuits, a plurality of output circuits, a shift register, and a buffer circuit. The plurality of input circuits, the plurality of output circuits, the shift register, and the buffer circuit are connected to terminals to which the power-source voltage V_{CCQ} and the ground voltage V_{SS} are supplied, respectively.

The data signal input/output terminals DQ0 to DQ7, the toggle signal input/output terminals DQS/DQS, and the terminals to which the power-source voltage V_{CCQ} are supplied are implemented, for example, by the bonding pad electrodes P_{X} described with reference to FIGS. 2 and 3. Data input via the data signal input/output terminals DQ0 to DQ7 is output from the buffer circuit to the cache memory C_{M}, the address register ADR, or the command register CMR in accordance with the internal control signal from the logic circuit CTR. Data output via the data signal input/output terminals DQ0 to DQ7 is input to the buffer circuit from the cache memory C_{M} or the status register STR in accordance with the internal control signal from the logic circuit CTR.

### Circuit Configuration of Logic Circuit CTR

The logic circuit CTR receives an external control signal from the controller die CD via external control terminals/CEn, CLE, ALE,/WE, RE, and/RE, and outputs the internal control signal to the input/output control circuit I/O in response to the reception. The external control terminals/CEn, CLE, ALE,/WE, RE, and/RE are implemented, for example, by the bonding pad electrodes P_{X} described with reference to FIGS. 2 and 3.

### Structure of Memory Die MD

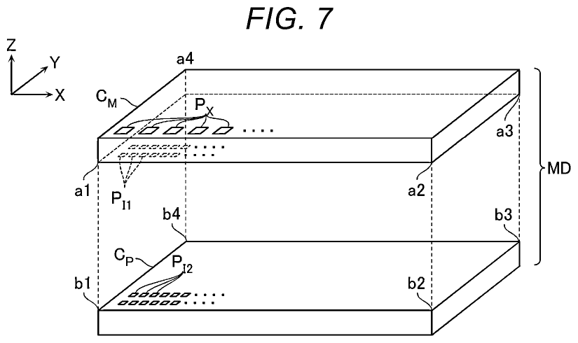

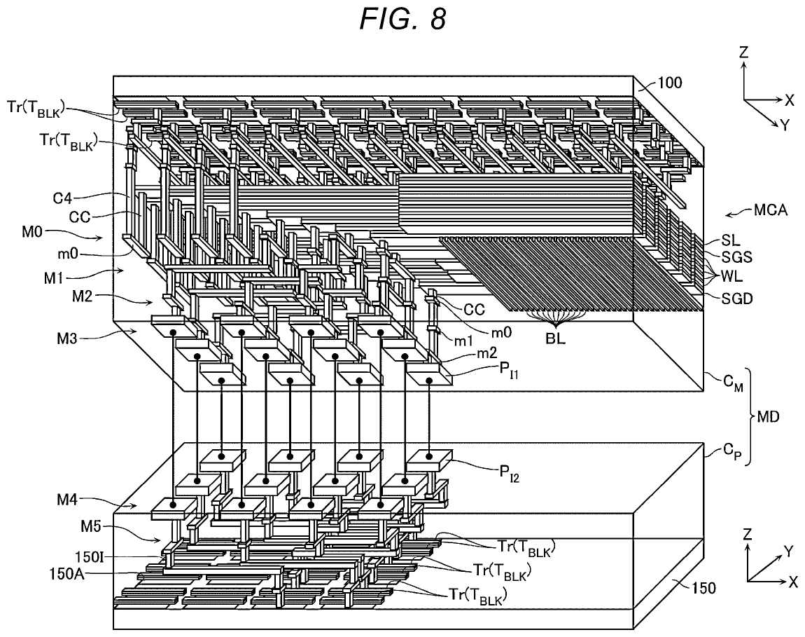

FIGS. 7 and 8 are exploded perspective views schematically illustrating the example of the configuration of the memory die MD. In FIG. 8, illustrations of the configuration of the transistor and the like are omitted in a partial region of the upper surface of a semiconductor substrate 150. In this region, the configuration of the transistor and the like may be arranged in a complicated pattern.

As illustrated in FIG. 7, the memory die MD includes a chip C_{M} and a chip C_{P}. The plurality of bonding pad electrodes P_{X} are provided on the upper surface of the chip C_{M}. As illustrated in FIG. 8, the chip C_{M} includes a semiconductor substrate 100, a plurality of transistors Tr provided on the lower surface of the semiconductor substrate 100, the memory cell array MCA provided below the transistors Tr, and a plurality of first bonding electrodes P_{I1} provided on the lower surface of the chip C_{M}. The chip C_{P} includes the semiconductor substrate 150, a plurality of transistors Tr provided on the upper surface of the semiconductor substrate 150, and a plurality of second bonding electrodes P_{I2} provided on the upper surface of the chip C_{P}. The memory cell array MCA and the plurality of transistors Tr in the chip C_{M} are electrically connected to the plurality of transistors Tr in the chip C_{P} via the plurality of first bonding electrodes P_{I1} and the plurality of second bonding electrodes P_{I2}. The plurality of transistors Tr provided in the chip C_{M} and the chip C_{P} function as a portion of the peripheral circuit PC (FIG. 4).

In the chips C_{M} and C_{P}, a surface on which the plurality of first bonding electrodes P_{I1} or the plurality of second bonding electrodes P_{I2} are provided is referred below to as a front surface, and a surface opposite to the front surface is referred below to as a rear surface.

The chip C_{M} and the chip C_{P} are disposed so that the front surface of the chip C_{M} faces the front surface of the chip C_{P}. The plurality of first bonding electrodes P_{I1} are provided respectively corresponding to the plurality of second bonding electrodes P_{I2}, and are arranged at locations bondable to the plurality of second bonding electrodes P_{I2}. The first bonding electrodes P_{I1} and the second bonding electrodes P_{I2} function as bonding electrodes for bonding the chip C_{M} and the chip C_{P} to each other and causing the chip C_{M} and the chip C_{P} to be electrically connected to each other.

In the example of FIG. 7, corners a1, a2, a3, and a4 of the chip C_{M} correspond to corners b1, b2, b3, and b4 of the chip C_{P}, respectively.

### Structure of Chip C_{M}

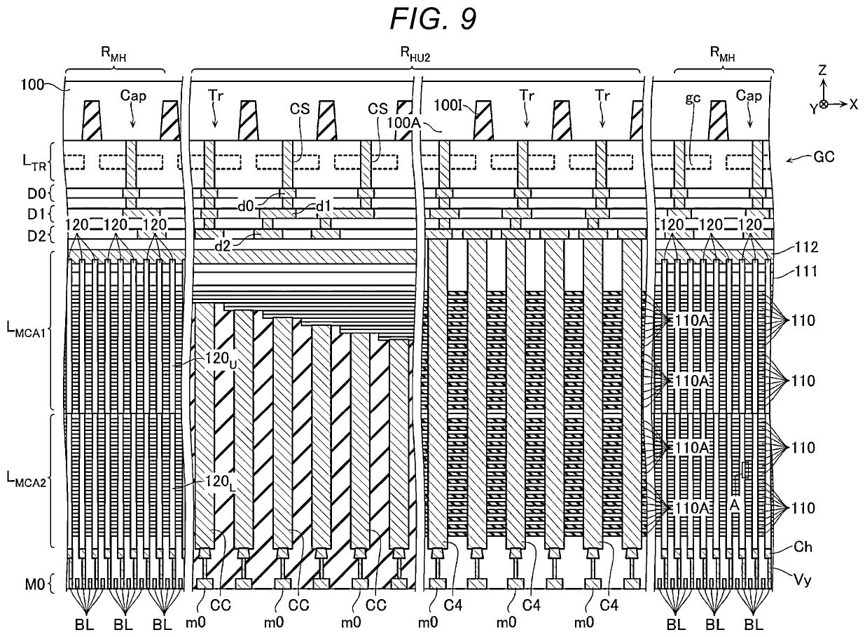

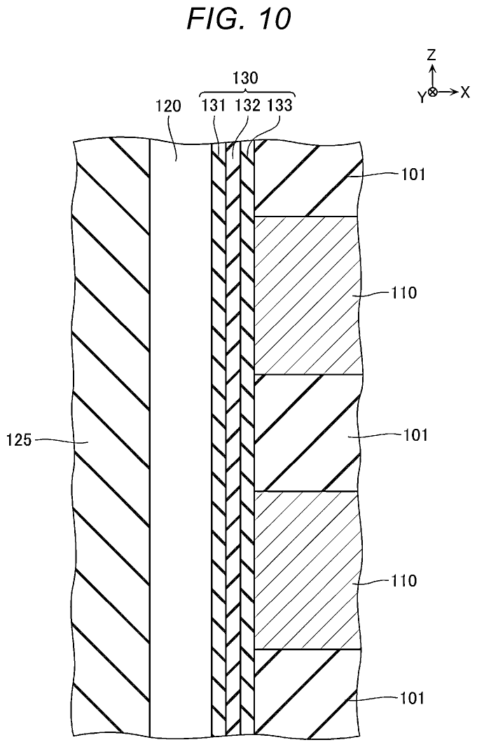

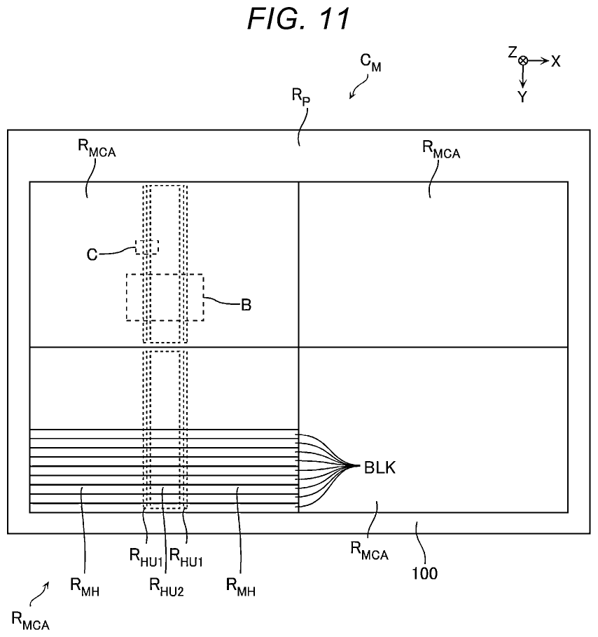

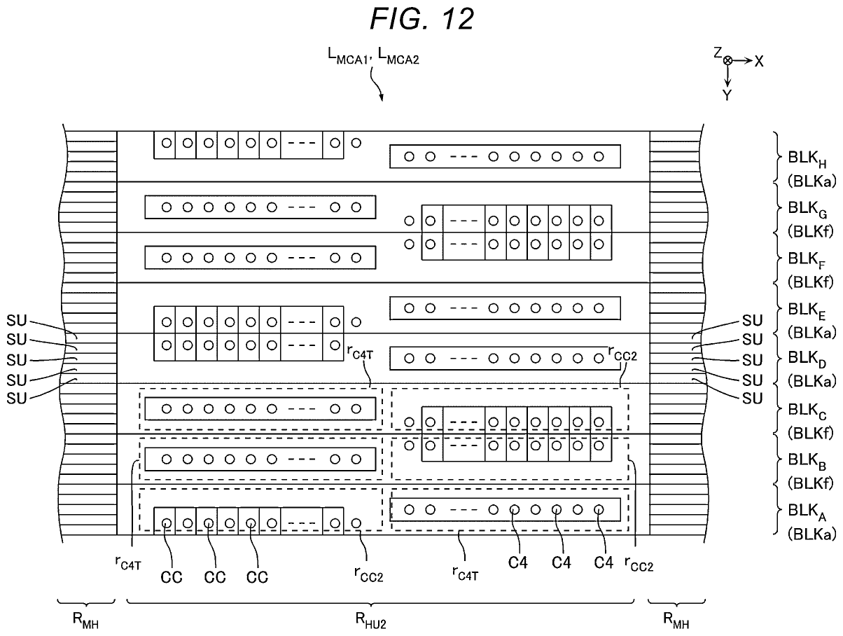

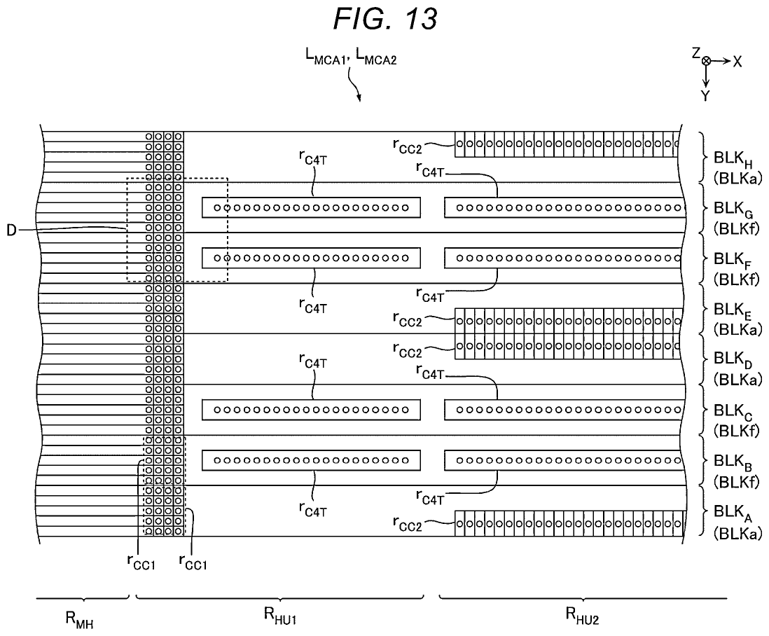

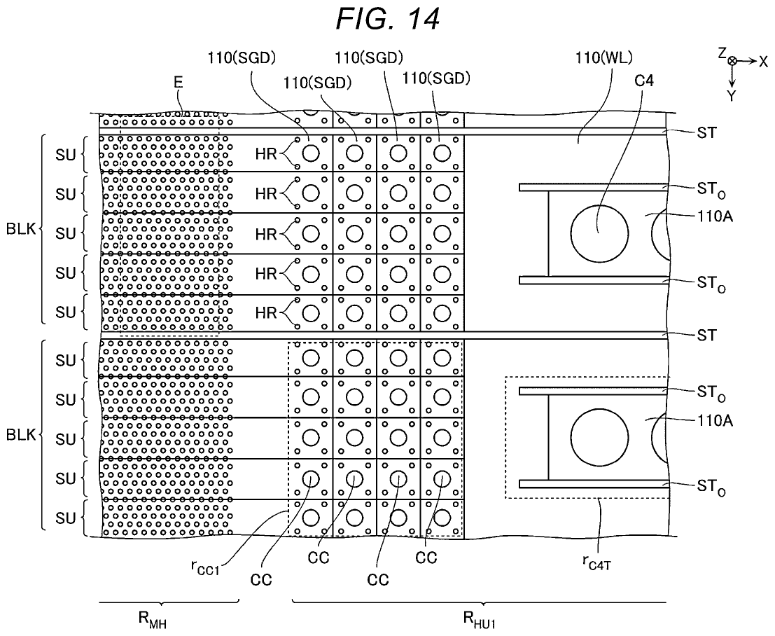

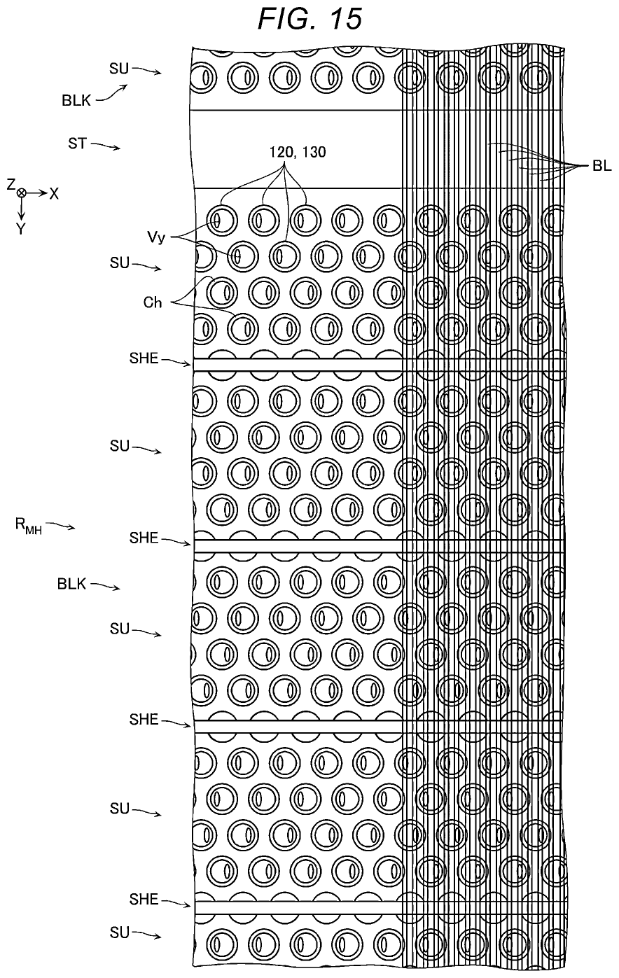

FIG. 9 is a cross-sectional view schematically illustrating the chip C_{M}. FIG. 10 is an enlarged view schematically illustrating a portion of the chip C_{M} indicated by A in FIG. 9. FIG. 11 is a bottom view schematically illustrating the chip C_{M}. FIG. 12 is an enlarged view schematically illustrating a portion of the chip C_{M} indicated by B in FIG. 11. FIG. 13 is an enlarged view schematically illustrating a portion of the chip C_{M} indicated by C in FIG. 11. FIG. 14 is an enlarged view schematically illustrating a portion of the chip C_{M} indicated by D in FIG. 13. FIG. 15 is an enlarged view schematically illustrating a portion of the chip C_{M} indicated by E in FIG. 14. In FIG. 12, illustration of a partial region (first hookup region R_{HU1} described later) is omitted.

For example, as illustrated in FIG. 9, the chip C_{M} includes a transistor layer L_{TR} provided on the lower surface of the semiconductor substrate 100, a wiring layer D0 provided below the transistor layer L_{TR}, a wiring layer D1 provided below the wiring layer D0, and a wiring layer D2 provided below the wiring layer D1. The chip C_{M} includes a memory cell array layer L_{MCA1} provided below the wiring layer D2, a memory cell array layer L_{MCA2} provided below the memory cell array layer L_{MCA1}, and a wiring layer M0 provided below the memory cell array layer L_{MCA2}. As illustrated in FIG. 8, the chip C_{M} further includes a wiring layer M1 provided below the wiring layer M0, a wiring layer M2 provided below the wiring layer M1, and a wiring layer M3 provided below the wiring layer M2.

For example, as illustrated in FIG. 11, the semiconductor substrate 100 is provided with four memory cell array regions R_{MCA} arranged in the X direction and the Y direction. The memory cell array region R_{MCA} includes two memory hole regions R_{MH} arranged in the X direction. Further, two first hookup regions R_{HU1} arranged in the X direction and a second hookup region R_{HU2} provided between the two first hookup regions are provided between the two memory hole regions R_{MH}. A peripheral region RP is provided at the end portion of the semiconductor substrate 100 in the Y direction.

In the following description, when the “memory cell array region R_{MCA} ”, the “memory hole region R_{MH} ”, the “first hookup region R_{HU1} ”, the “second hookup region R_{HU2} ”, or the “peripheral region RP” is described, it is assumed that the described region includes not only the region in the memory cell array layers L_{MCA1} and L_{MCA2} but also the corresponding region in other layers (semiconductor substrate 100, transistor layer L_{TR}, and wiring layers D0, D1, D2, M0, M1, and M2) included in the chip C_{M} and the corresponding region in the layers included in the chip C_{P}.

### Structure of Semiconductor Substrate 100

The semiconductor substrate 100 is, for example, a semiconductor substrate configured with P-type silicon (Si) containing P-type impurities such as boron (B). For example, as illustrated in FIG. 9, an active region 100A and an insulating region 100I made of silicon oxide (SiO₂) or the like are provided on the front surface of the semiconductor substrate 100. The active region 100A may be an N-type well region containing N-type impurities such as phosphorus (P), a P-type well region containing P-type impurities such as boron (B), or a semiconductor substrate region in which the N-type well region and the P-type well region are not provided.

### Structure of Transistor Layer L_{TR}

For example, as illustrated in FIG. 9, a wiring layer GC is provided on the lower surface of the semiconductor substrate 100 via an insulating layer (not illustrated). The wiring layer GC includes a plurality of electrodes gc facing the front surface of the semiconductor substrate 100. Each region of the semiconductor substrate 100 and the plurality of electrodes gc included in the wiring layer GC are connected to contacts CS, respectively.

The active regions 100A of the semiconductor substrate 100 function as channel regions of a plurality of transistors Tr constituting the peripheral circuit PC, one electrodes of a plurality of capacitors Cap, and the like, respectively.

The plurality of electrodes gc included in the wiring layer GC functions as gate electrodes of the plurality of transistors Tr constituting the peripheral circuit PC, the other electrodes of the plurality of capacitors Cap, and the like, respectively.

The contact CS extends in the Z direction and is connected to the lower surface of the semiconductor substrate 100 or the lower surface of the electrode gc at the upper end of the contact CS. An impurity region containing N-type impurities P-type impurities is provided at a portion at which the contact CS and the semiconductor substrate 100 are connected to each other. The contact CS may include, for example, a laminated film of a barrier conductive film made of titanium nitride (TiN) or the like and a metal film made of tungsten (W) or the like.

### Structure of Wiring Layers D0, D1, and D2

For example, as illustrated in FIG. 9, a plurality of wirings included in the wiring layers D0, D1, and D2 are electrically connected to at least one of the components of the memory cell array layer L_{MCA}, the components of the transistor layer L_{TR}, and the semiconductor substrate 100.

The wiring layers D0, D1, and D2 include a plurality of wirings d0, d1, and d2, respectively. The plurality of wirings d0, d1, and d2 may include, for example, a laminated film of a barrier conductive film made of titanium nitride (TiN), tantalum nitride (TaN) or the like and a metal film made of tungsten (W), copper (Cu), aluminum (Al), or the like.

Structure of Memory Cell Array Layers L_{MCA1} and L_{MCA2} in Memory Hole Region R_{MH}

For example, as illustrated in FIG. 12, a plurality of memory blocks BLK (in the example in FIG. 12, memory blocks BLK_{A} to BLK_{H}) arranged in the Y direction are provided in the memory cell array layers L_{MCA1} and L_{MCA2}.

In the following description, the first memory block BLK, the 4nB-th (nB is a positive integer of 1 or more) memory block BLK, the (4nB+1)th memory block BLK, and the (4nB+4)th memory block BLK counting from one side (for example, negative side in the Y direction in FIG. 12) in the Y direction may be referred to as memory blocks BLKa. In FIG. 12, memory blocks BLK_{A}, BLK_{D}, BLK_{E}, and BLK_{H} are exemplified as the memory block BLKa. In the following description, the second memory block BLK, the third memory block BLK, the (4nB+2) th memory block BLK, and the (4nB+3) th memory block BLK counting from the one side (for example, negative side in the Y direction in FIG. 12) in the Y direction may be referred to as memory blocks BLKf. In FIG. 12, memory blocks BLK_{B}, BLK_{C}, BLK_{F}, and BLK_{G} are exemplified as the memory block BLKf.

For example, as illustrated in FIG. 14, the memory block BLK includes a plurality of string unit SU arranged in the Y direction. An inter-block insulating layer ST made of silicon (SiO₂) or the like is provided between two memory blocks BLK adjacent to each other in the Y direction. For example, as illustrated in FIG. 15, an inter-string unit insulating layer SHE made of silicon oxide (SiO₂) or the like is provided between two string units SU adjacent to each other in the Y direction.

For example, as illustrated in FIG. 9, the memory block BLK includes a plurality of conductive layers 110 arranged in the Z direction and a plurality of semiconductor pillars 120 extending in the Z direction. For example, as illustrated in FIG. 10, the memory block BLK includes a plurality of gate insulating films 130 provided between the plurality of conductive layers 110 and the plurality of semiconductor pillars 120, respectively.

The conductive layer 110 is a substantially plate-shaped conductive layer extending in the X direction. The conductive layer 110 includes a plurality of through-holes provided corresponding to the semiconductor pillars 120 (FIG. 9). The inner peripheral surfaces of the plurality of through-holes face the outer peripheral surfaces of the semiconductor pillars 120 via the gate insulating films 130, respectively. The conductive layer 110 may include a laminated film of a barrier conductive film made of titanium nitride (TiN) or the like and a metal film made of tungsten (W) or the like. The conductive layer 110 may contain, for example, polycrystalline silicon containing impurities such as phosphorus (P) or boron (B). Insulating layers 101 (FIG. 10) made of silicon oxide (SiO₂) or the like are provided between the plurality of conductive layers 110 arranged in the Z direction.

As illustrated in FIG. 9, a conductive layer 111 is provided above the conductive layer 110. The conductive layer 111 may contain, for example, polycrystalline silicon containing impurities such as phosphorus (P) or boron (B). An insulating layer made of silicon oxide (SiO₂) or the like is provided between the conductive layer 111 and the conductive layer 110.

A conductive layer 112 is provided above the conductive layer 111. The conductive layer 112 may contain, for example, polycrystalline silicon containing impurities such as phosphorus (P) or boron (B). The conductive layer 112 may contain, for example, metal such as tungsten (W) or may include a conductive layer made of tungsten silicide or the like or another conductive layer. An insulating layer made of silicon oxide (SiO₂) or the like is provided between the conductive layer 112 and the conductive layer 111.

The conductive layer 112 functions as the source line SL (FIG. 5). The source line SL is provided in common for all the memory blocks BLK included in the memory cell array region R_{MCA} (FIG. 11), for example.

The conductive layer 111 functions as the source-side selection gate line SGSb (FIG. 5) and the gate electrodes of the plurality of source-side select transistors STSb connected to the source-side selection gate line SGSb. The conductive layer 111 is electrically independent for each memory block BLK.

Among the plurality of conductive layers 110, one or a plurality of conductive layers 110 located on the uppermost layer function as the source-side selection gate line SGS (FIG. 5) and the gate electrodes of the plurality of source-side select transistors STS connected to the source-side selection gate line SGS. The plurality of conductive layers 110 are electrically independent for each memory block BLK.

A plurality of conductive layers 110 located below the above-described conductive layers 110 function as the word lines WLs (FIG. 5) and the gate electrodes of the plurality of memory cells MC (FIG. 5) connected to the word lines WLs. The plurality of conductive layers 110 are electrically independent from each other for each memory block BLK.

One or a plurality of conductive layers 110 located below the above-described conductive layers 110 function as the drain-side selection gate line SGD and the gate electrodes of the plurality of drain-side select transistors STD (FIG. 5) connected to the drain-side selection gate line SGD. The widths of the plurality of conductive layers 110 that function as the drain-side selection gate line SGD in the Y direction are smaller than the widths of the other conductive layers 110 that function as the word lines WLs. The inter-string unit insulating layer SHE (FIG. 15) is provided between the two conductive layers 110 that function as the drain-side selection gate line SGD and are adjacent to each other in the Y direction. The plurality of conductive layers 110 functioning as the drain-side selection gate line SGD are electrically independent for each string unit SU.

For example, as illustrated in FIG. 15, the semiconductor pillars 120 are arranged in the X direction and the Y direction in a predetermined pattern. The semiconductor pillars 120 function as channel regions of the plurality of memory cells MC and select transistors (STD and STS) included in one memory string MS (FIG. 5). The semiconductor pillar 120 is a semiconductor layer made of polycrystalline silicon (Si), for example. For example, the semiconductor pillar 120 has, for example, a substantially cylindrical shape, and an insulating layer 125 (FIG. 10) made of silicon oxide or the like is provided at a central portion of the semiconductor pillar 120. An outer peripheral surface of each of the semiconductor pillars 120 is surrounded by the conductive layer 110 and faces the conductive layer 110.

As illustrated in FIG. 9, the semiconductor pillar 120 includes a semiconductor portion 120 provided in the memory cell array layer L_{MCA1} and a semiconductor portion 120_{L} provided in the memory cell array layer L_{MCA2}.

The semiconductor portion 120_{U} faces a plurality of conductive layers 110 provided in the memory cell array layer L_{MCA1}. An impurity region containing N-type impurities such as phosphorus (P) is provided at an upper end portion of the semiconductor portion 120_{U}. Such an impurity region is connected to the conductive layer 112 (FIG. 9).

The semiconductor portion 120_{L} faces the plurality of conductive layers 110 provided in the memory cell array layer L_{MCA2}. An impurity region containing N-type impurities such as phosphorus (P) is provided at a lower end portion of the semiconductor portion 120_{L}. Such an impurity region is connected to the bit line BL via a contact Ch and a contact Vy.

The gate insulating film 130 (FIG. 10) has a substantially cylindrical shape that covers the outer peripheral surface of the semiconductor pillar 120. For example, as illustrated in FIG. 10, the gate insulating film 130 includes a tunnel insulating film 131, a charge storage film 132, and a block insulating film 133, which are stacked between the semiconductor pillar 120 and the conductive layer 110. The tunnel insulating film 131 and the block insulating film 133 are insulating films made of silicon oxide (SiO₂), for example. The charge storage film 132 is a film that is made of silicon nitride (Si₃N₄) and is capable of storing charges, for example. The tunnel insulating film 131, the charge storage film 132, and the block insulating film 133 have a substantially cylindrical shape, and extend in the Z direction along the outer peripheral surface of the semiconductor pillar 120.

FIG. 10 illustrates an example in which the gate insulating film 130 includes the charge storage film 132 made of silicon nitride or the like. However, the gate insulating film 130 may include, for example, a floating gate made of polycrystalline silicon containing N-type or P-type impurities.

Structure of Memory Cell Array Layer L_{MCA2} in First Hookup Region R_{HU1}

As illustrated in FIG. 13, contact connection small-regions r_{CC1} provided respectively corresponding to the memory blocks BLK are provided in the first hookup region R_{HU1}. A contact connection small-region r_{C4T} provided corresponding to the memory block BLKf is provided in the first hookup region R_{HU1}.

As illustrated in FIG. 14, end portions of the plurality of conductive layers 110 functioning as the drain-side selection gate line SGD, in the X direction, are provided in the contact connection small-region r_{CC1}. A plurality of contacts CC arranged in a matrix when viewed from the Z direction are provided in the contact connection small-region r_{CC1}. The plurality of contacts CC extend in the Z direction and are connected to the conductive layers 110 at the upper ends of the contacts CC. The contact CC may include, for example, a laminated film of a barrier conductive film made of titanium nitride (TiN) or the like and a metal film made of tungsten (W) or the like.

Among the plurality of contacts CC arranged in the X direction, the contact CC closest to the memory hole region R_{MH} is connected to the first conductive layer 110 counting from the bottom. The second contact CC closest to the memory hole region R_{MH} is connected to the second conductive layer 110 counting from the bottom. In the followings, similarly, the a-th (a is a positive integer of 1 or more) contact CC closest to the memory hole region R_{MH} is connected to the a-th conductive layer 110 counting from the bottom. Some of the plurality of contacts CC are connected to the drain electrodes of the transistors Tr in the chip C_{M} or the chip C_{P} via the wiring m0 and the like in the wiring layer M0.

Among the plurality of contacts CC, the contacts corresponding to the memory blocks BLKf (FIG. 13) are connected to contacts C4 in the contact connection small-region r_{C4T} corresponding to the memory blocks BLKf, respectively, and are electrically connected to the transistors Tr provided on the semiconductor substrate 100 in the chip C_{M} via the contacts C4. Among the plurality of contacts CC, the contacts corresponding to the memory blocks BLKa (FIG. 13) are connected to contacts C4 in the contact connection small-region r_{C4T} corresponding to the memory blocks BLKf adjacent to the memory blocks BLKa, respectively, and are electrically connected to the transistors Tr provided on the semiconductor substrate 100 in the chip C_{M} via the contacts C4.

For example, as illustrated in FIG. 14, a support structure HR provided near the contact CC is provided in the first hookup region R_{HU1}. The support structure HR extends in the Z direction and is connected to the conductive layer 112 at the upper end of the support structure HR. The support structure HR includes an insulating layer made of silicon oxide (SiO₂), for example.

Two insulating layers S_{TO} arranged in the Y direction are provided in the contact connection small-region r_{C4T}. The two insulating layers S_{TO} are provided between two inter-block insulating layers ST arranged in the Y direction. For example, as illustrated in FIG. 9, the plurality of insulating layers 110A arranged in the Z direction and the plurality of contacts C4 extending in the Z direction are provided between the two insulating layers S_{TO}.

The insulating layer S_{TO} (FIG. 14) extends in the X direction and the Z direction and is connected to the conductive layer 112 at the upper end of the insulating layer S_{TO}. The insulating layer S_{TO} contains, for example, silicon oxide (SiO₂).

The insulating layer 110A is a substantially plate-shaped insulating layer extending in the X direction. The insulating layer 110A may include an insulating layer made of silicon nitride (Si₃N₄) or the like. Insulating layers made of silicon oxide (SiO₂) or the like are provided between the plurality of insulating layers 110A arranged in the Z direction.

The plurality of contacts C4 are arranged in the X direction. The contact C4 may include a laminated film of a barrier conductive film made of titanium nitride (TiN) or the like and a metal film made of tungsten (W) or the like. For example, as illustrated in FIG. 9, the outer peripheral surface of the contact C4 is surrounded by the respective insulating layers 110A, and is connected to the insulating layers 110A. For example, as illustrated in FIG. 9, the contact C4 extends in the Z direction, is connected to the wiring m0 in the wiring layer M0 at the lower end of the contact C4, and is connected to the wiring d2 in the wiring layer D2 at the upper end of the contact C4.

The plurality of conductive layers 110 functioning as the drain-side selection gate line SGD may be connected to the transistors Tr in the chip C_{P} instead of the transistors Tr in the chip C_{M}. In this case, the plurality of conductive layers 110 are electrically connected to the transistors Tr provided on the semiconductor substrate 150 of the chip C_{P} via the contacts CC, the first bonding electrode P_{I1}, and the second bonding electrode P_{I2}. Further, in this case, the contact connection small-region r_{C4T} in the first hookup region R_{HU1} may also be omitted.

Structure of Memory Cell Array Layers L_{MCA1} and L_{MCA2} in Second Hookup Region R_{HU2}

As illustrated in FIG. 12, a plurality of contact connection small-regions r_{CC2} and a plurality of contact connection small-regions r_{C4T} re provided in a region of the second hookup region R_{HU2} on one side (for example, negative side in the X direction in FIG. 12) in the X direction. The plurality of contact connection small-regions r_{CC2} are provided at positions corresponding to the memory blocks BLKa. The plurality of contact connection small-regions r_{C4T} are provided at positions corresponding to the memory blocks BLKf.

As illustrated in FIG. 12, a plurality of contact connection small-regions r_{CC2} and a plurality of contact connection small-regions r_{C4T} are also provided in a region of the second hookup region R_{HU2} on the other side (for example, positive side in the X direction in FIG. 12) in the X direction. The plurality of contact connection small-regions r_{CC2} are provided at positions corresponding to the memory blocks BLKf. The plurality of contact connection small-regions r_{C4T} are provided at positions corresponding to the memory blocks BLKa.

Some of the plurality of conductive layers 110 functioning as the word line WL or the source-side selection gate line SGS are provided in the contact connection small-region r_{CC2}. A plurality of contacts CC arranged in the X direction are provided in the contact connection small-region r_{CC2}. For example, as illustrated in FIG. 9, the plurality of contacts CC extend in the Z direction and are connected to the conductive layers 110 at the upper ends of the contacts CC. The contact CC may include, for example, a laminated film of a barrier conductive film made of titanium nitride (TiN) or the like and a metal film made of tungsten (W) or the like.

Among the plurality of contacts CC arranged in the X direction, the contact CC closest to the memory hole region R_{MH} is connected to the first conductive layer 110 counting from the top. The second contact CC closest to the memory hole region R_{MH} is connected to the second conductive layer 110 counting from the top. In the followings, similarly, the b-th (b is a positive integer of 1 or more) contact CC closest to the memory hole region R_{MH} is connected to the b-th conductive layer 110 counting from the top.

For example, as illustrated in FIGS. 8 and 12, some of the plurality of contacts CC are connected to the contacts C4 in the contact connection small-region r_{C4T} corresponding to the memory blocks BLK adjacent to the memory block BLK, via the wiring m0 extending in the Y direction, respectively, and are electrically connected to the transistors Tr provided on the semiconductor substrate 100 in the chip C_{M} via the contacts C4. Some of the plurality of contacts CC are electrically connected to the transistors Tr provided on the semiconductor substrate 150 of the chip C_{P} via the first bonding electrode P_{I1} and the second bonding electrode P_{I2}, respectively.

### Structure of Wiring Layers M0, M1, M2, and M3

As illustrated in FIG. 8, the plurality of wirings included in the wiring layers M0, M1, M2, and M3 are electrically connected to at least one of the components in the memory cell array layers L_{MCA1} and L_{MCA2}, the components in the transistor layer L_{TR}, and the components in the chip C_{P}.

The wiring layers M0, M1, and M2 include a plurality of wirings m0, m1, and m2, respectively. The plurality of wirings m0, m1, and m2 may include, for example, a laminated film of a barrier conductive film made of titanium nitride (TiN), tantalum nitride (TaN) or the like and a metal film made of tungsten (W), copper (Cu), or the like. Some of the plurality of wirings m0 function as the bit lines BL (FIG. 5). For example, as illustrated in FIG. 15, the bit lines BL are arranged in the X direction and extend in the Y direction. Each of the plurality of bit lines BL is connected to one semiconductor pillar 120 included in each string unit SU.

For example, as illustrated in FIG. 8, the wiring layer M3 includes a plurality of first bonding electrodes P_{I1}. The plurality of first bonding electrodes PI may include, for example, a laminated film of a barrier conductive film made of titanium nitride (TiN), tantalum nitride (TaN) or the like and a metal film made of copper (Cu), or the like.

### Structure of Chip C_{P}

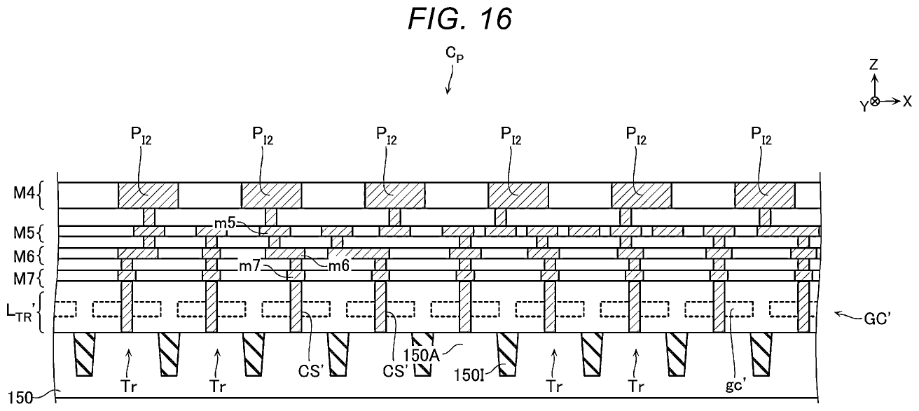

FIG. 16 is a cross-sectional view schematically illustrating the chip C_{P}. The chip C_{P} includes, for example, a transistor layer L_{TR}′ provided on the upper surface of the semiconductor substrate 150, a wiring layer M7 provided above the transistor layer L_{TR}′, a wiring layer M6 provided above the wiring layer M7, a wiring layer M5 provided above the wiring layer M6, and a wiring layer M4 provided above the wiring layer M5.

The semiconductor substrate 150 is a semiconductor substrate configured with P-type silicon (Si) containing P-type impurities such as boron (B), for example. An active region 150A and an insulating region 150I made of silicon oxide (SiO₂) or the like are provided on the front surface of the semiconductor substrate 150. The active region 150A may be an N-type well region containing N-type impurities such as phosphorus (P), a P-type well region containing P-type impurities such as boron (B), or a semiconductor substrate region in which the N-type well region and the P-type well region are not provided.

### Structure of Transistor Layer L_{TR}′

For example, as illustrated in FIG. 16, a wiring layer GC′ is provided on the upper surface of the semiconductor substrate 150 via an insulating layer (not illustrated). The wiring layer GC′ includes a plurality of electrodes gc′ facing the front surface of the semiconductor substrate 150. The plurality of electrodes gc′ included in each region of the semiconductor substrate 150 and the wiring layer GC′ are connected to contacts CS′, respectively.

The active regions 150A of the semiconductor substrate 150 function as channel regions of a plurality of transistors Tr constituting the peripheral circuit PC, one electrodes of a plurality of capacitors, and the like, respectively.

The plurality of electrodes gc′ included in the wiring layer GC′ functions as gate electrodes of the plurality of transistors Tr constituting the peripheral circuit PC, the other electrodes of the plurality of capacitors, and the like, respectively.

The contact CS′ extends in the Z direction and is connected to the upper surface of the semiconductor substrate 150 or the upper surface of the electrode gc′ at the lower end of the contact CS′. An impurity region containing N-type impurities or P-type impurities is provided at a portion at which the contact CS′ and the semiconductor substrate 150 are connected to each other. The contact CS′ may include, for example, a laminated film of a barrier conductive film made of titanium nitride (TiN) or the like and a metal film made of tungsten (W) or the like.

### Structure of Wiring Layers M7, M6, and M5

A plurality of wirings included in the wiring layers M7, M6, and M5 are electrically connected to at least one of the components in the transistor layer L_{TR}′ and the semiconductor substrate 150.

The wiring layers M7, M6, and M5 include a plurality of wirings m7, m6, and m5, respectively. The plurality of wirings m7, m6, and m5 may include, for example, a laminated film of a barrier conductive film made of titanium nitride (TiN), tantalum nitride (TaN) or the like and a metal film made of tungsten (W), copper (Cu), aluminum (Al), or the like.

The wiring layer M4 includes a plurality of second bonding electrodes P_{I2}. The plurality of second bonding electrodes P_{I2} may include, for example, a laminated film of a barrier conductive film made of titanium nitride (TiN), tantalum nitride (TaN) or the like and a metal film made of copper (Cu), or the like.

### Arrangement of Transistors Tr Constituting Peripheral Circuit PC

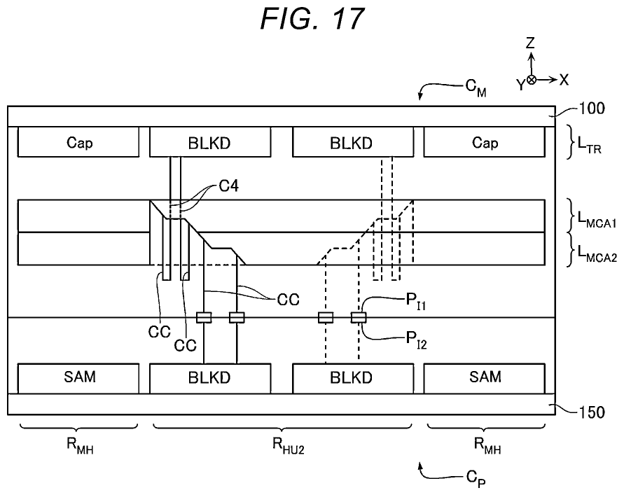

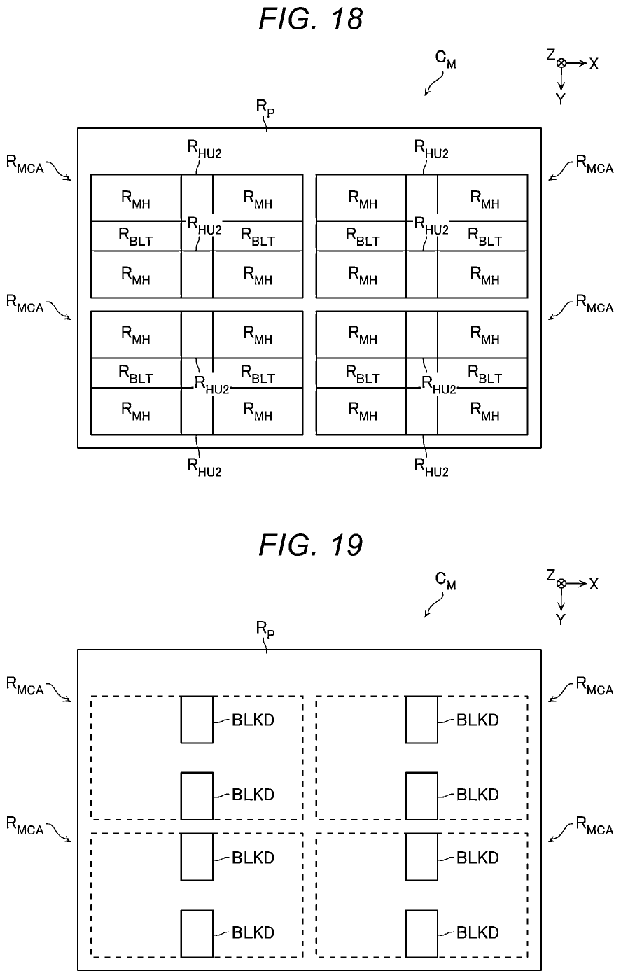

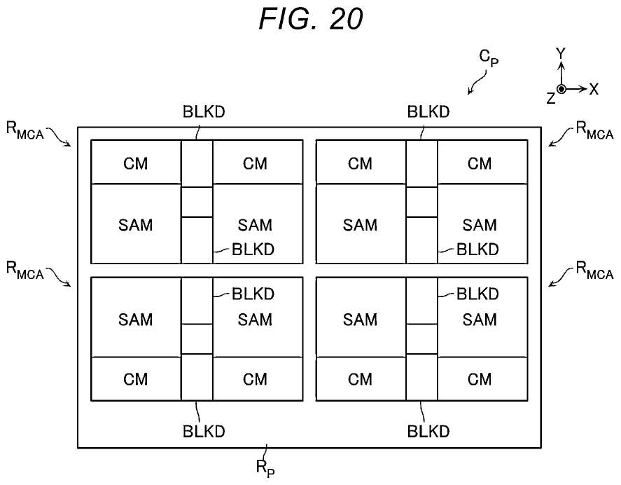

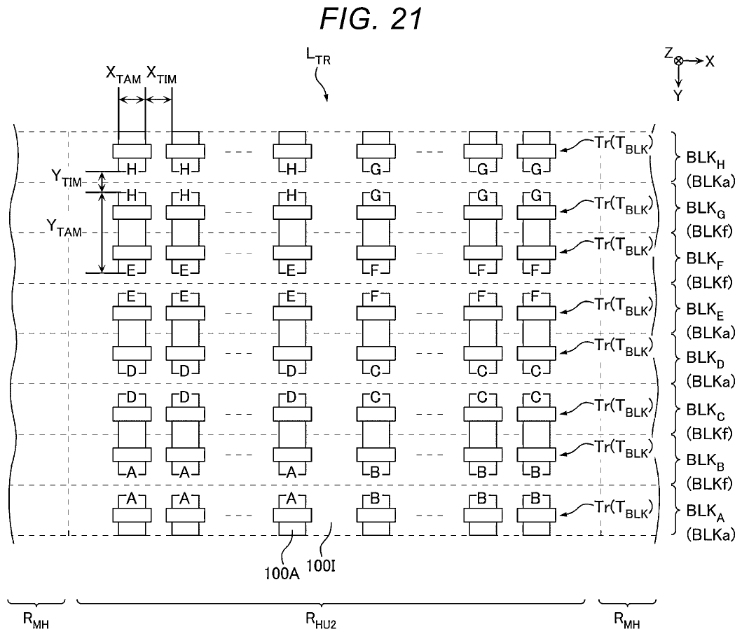

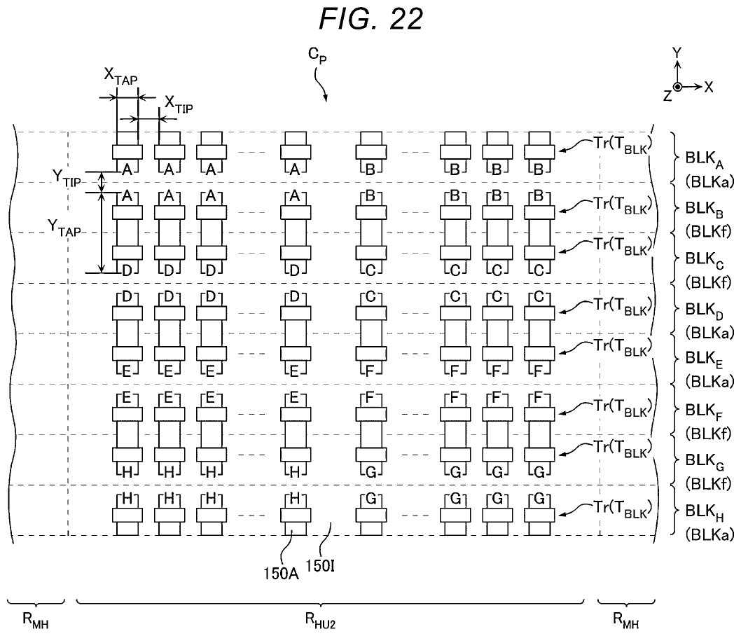

Next, the arrangement of the transistors Tr constituting the peripheral circuit PC will be described with reference to FIGS. 17 to 22. FIG. 17 is a cross-sectional view schematically illustrating the configuration of the memory die MD. FIG. 18 is a bottom view schematically illustrating the configuration of the memory cell array layers L_{MCA1} and L_{MCA2} in the chip C_{M}. FIG. 19 is a bottom view schematically illustrating the configuration of the transistor layer L_{TR} in the chip C_{M}. FIG. 20 is a plan view schematically illustrating the configuration of the chip C_{P}. FIG. 21 is a bottom view schematically illustrating the transistor layer L_{TR} in the chip C_{M}. FIG. 22 is a plan view schematically illustrating a partial configuration of the chip C_{P}. FIGS. 21 and 22 illustrate the components provided at positions overlapping the components in FIG. 12 when viewed from the Z direction.

FIG. 18 illustrates a region R_{BLT} in the memory cell array region R_{MCA}, which is not described with reference to FIG. 11. For example, components for connecting the bit lines BL (FIG. 9) and the transistors Tr in the chip C_{P} to each other are provided in the region R_{BLT}. In FIGS. 17 to 22, the illustration of the first hookup region R_{HU1} is omitted similar to FIG. 12.

### Arrangement of Transistors Tr in Chip C_{M}

As described above, the plurality of transistors Tr are provided in the transistor layer L_{TR} of the chip C_{M}. As illustrated in FIGS. 18 and 19, among the plurality of transistors Tr, the transistor Tr provided in the second hookup region R_{HU2} functions as a portion (transistor T_{BLK}) of the block decoder BLK_{D} described with reference to FIG. 6. For example, the capacitors Cap (FIG. 17) may be provided in other regions instead of the transistors Tr. For example, as illustrated in FIG. 9, the capacitor Cap may include an active region 100A, an electrode gc, and a gate insulating film provided between the active region 100A and the electrode gc, similar to the transistor Tr. The film thickness (thickness in the Z direction) of the electrode gc and the gate insulating film constituting the capacitor Cap may be substantially equal to the film thickness (thickness in the Z direction) of the electrode gc and the gate insulating film constituting the transistor Tr. The capacitor Cap may be connected between the bonding pad electrode P_{X} to which the power-source voltage V_{CC} or V_{CCQ} is supplied, and the bonding pad electrode P_{X} to which the ground voltage V_{SS} is supplied.

In the example of FIG. 21, a plurality of transistor rows arranged in the Y direction are provided in the second hookup region R_{HU2} to correspond to the plurality of memory blocks BLK arranged in the Y direction. Each transistor row includes a plurality of transistors Tr arranged in the X direction.

In the example of FIG. 21, a plurality of transistors Tr are provided at positions corresponding to the contact connection small-regions r_{CC2} (see FIG. 12) including the contacts CC connected to the memory blocks BLK_{A}. A plurality of transistors Tr are provided at positions which correspond to BLK_{B} and correspond to the contact connection small-regions r_{C4T} (see FIG. 12) including the contacts C4 connected to the memory block BLK_{A}. Each of the drain electrodes of the plurality of transistors Tr is electrically connected to the word line WL or the like in the memory block BLK_{A} via the contact C4. Each of the drain electrodes of the plurality of transistors Tr are electrically connected to any of the wirings m7, m6, and m5 functioning as the wiring CG (FIG. 6) via the contacts C4 in the second hookup region R_{HU2}, the wirings m0, m1, and m2, the first bonding electrode P_{I1}, and the second bonding electrode P_{I2}.

Similarly, in the example of FIG. 21, a plurality of transistors Tr are provided at positions corresponding to the contact connection small-regions r_{CC2} including the contacts CC connected to any memory block BLK. A plurality of transistors Tr are provided at positions which correspond to a memory block BLK adjacent to the above memory block BLK and correspond to the contact connection small-regions r_{C4T} including the contacts C4 connected to the above memory block BLK. Each of the drain electrodes of the plurality of transistors Tr is electrically connected to the word line WL or the like in the corresponding memory block BLK via the contact C4. Each of the drain electrodes of the plurality of transistors Tr are electrically connected to any of the wirings m7, m6, and m5 functioning as the wiring CG (FIG. 6) via the contacts C4 in the second hookup region R_{HU2}, the wirings m0, m1, and m2, the first bonding electrode P_{I1}, and the second bonding electrode P_{I2}.

In the example of FIG. 21, the width of the active region 100A corresponding to the transistor T_{BLK} is set as a width X_{TAM}, and the length of the active region 100A corresponding to the transistor T_{BLK} in the Y direction is set as Y_{TAM}. In the example of FIG. 21, the distance between two adjacent active regions 100A in the X direction is set as a distance X_{TIM}, and the distance between the two adjacent active regions 100A in the Y direction is set as a distance Y_{TIM}.

### Arrangement of Transistors Tr in Chip C_{P}

As described above, the plurality of transistors Tr are provided on the front surface of the semiconductor substrate 150 of the chip C_{P}. As illustrated in FIGS. 18 and 20, among the plurality of transistors Tr, the transistor Tr provided in the second hookup region R_{HU2} functions as a portion (transistor T_{BLK}) of the block decoder BLK_{D} described with reference to FIG. 6. The transistor provided in the memory hole region R_{MH} functions as a portion of the sense amplifier module SAM or the cache memory C_{M} (FIG. 4).

In the example of FIG. 22, a plurality of transistor rows arranged in the Y direction are provided in the second hookup region R_{HU2} to correspond to the plurality of memory blocks BLK arranged in the Y direction. Each transistor row includes a plurality of transistors Tr arranged in the X direction.

In the example of FIG. 22, a plurality of transistors Tr are provided at positions corresponding to the contact connection small-regions r_{CC2} (see FIG. 12) including the contacts CC connected to the memory blocks BLKA. A plurality of transistors Tr are provided at positions which correspond to BLK_{B} and correspond to the contact connection small-regions r_{C4T} (see FIG. 12) including the contacts C4 connected to the memory block BLK_{A}. Each of the plurality of transistors Tr is electrically connected to the word line WL or the like in the memory block BLK_{A} via the first bonding electrode P_{I1} and the second bonding electrode P_{I2}.

Similarly, in the example of FIG. 22, a plurality of transistors Tr are provided at positions corresponding to the contact connection small-regions r_{CC2} including the contacts CC connected to any memory block BLK. A plurality of transistors Tr are provided at positions which correspond to a memory block BLK adjacent to the above memory block BLK and correspond to the contact connection small-regions r_{C4T} including the contacts C4 connected to the above memory block BLK. Each of the plurality of transistors Tr is electrically connected to the word line WL or the like in the corresponding memory block BLK via the first bonding electrode P_{I1} and the second bonding electrode P_{I2}.

In the example of FIG. 22, the width of the active region 150A corresponding to the transistor T_{BLK}, in the X direction, is set as X_{TAP}, and the length of the active region 150A corresponding to the transistor T_{BLK}, in the Y direction, is set as Y_{TAP}. In the example of FIG. 22, the distance between two adjacent active regions 100A in the X direction is set as a distance X_{TIP}, and the distance between the two adjacent active regions 100A in the Y direction is set as a distance YIP.

In the examples of FIGS. 21 and 22, the width X_{TAP} is smaller than the width X_{TAM}. The distance X_{TIP} is smaller than the distance X_{TIM}. The length Y_{TAP} is equal to the length Y_{TAM}. The distance Y_{TIP} is equal to the distance Y_{TIM}. For example, the width of the entire region in which the transistors T_{BLK} are provided on the front surface of the semiconductor substrate 100, in the X direction, may be larger than the width of the entire region in which the transistors T_{BLK} are provided on the front surface of the semiconductor substrate 150, in the X direction. In such a case, for example, all the transistors T_{BLK} included in the chip C_{P} may be provided within the range of the second hookup region R_{HU2}, and the transistors T_{BLK} included in the chip C_{P} may be provided over the second hookup region R_{HU2}, and the first hookup region R_{HU1}, and a portion of the memory hole region R_{MH}.

### Effect of First Embodiment

As described above, the plurality of conductive layers 110 are electrically connected to the plurality of transistors T_{BLK}. The transistor T_{BLK} is provided corresponding to the conductive layer 110. That is, the number of transistors T_{BLK} is equal to the number of conductive layers 110. Here, when the semiconductor storage device is highly integrated in the Z direction, the number of conductive layers 110 stacked in the Z direction increases. In this case, the number of transistors T_{BLK} also increases corresponding to the number of conductive layers 110. Here, considering the wiring layout connected to the circuit of the transistor T_{BLK}, it is preferable that the circuit of the transistor T_{BLK} extends from the second hookup region R_{HU2} in the X direction and is arranged, which contributes to the reduction of the wiring area. However, in a case where the circuit area of the transistor T_{BLK} becomes large in the X direction, there is a concern that high density integration of the semiconductor storage device in the X direction has a difficulty, and high density integration is hindered.

Thus, in the first embodiment, both the transistor Tr in the chip C_{P} and the transistor Tr in the chip C_{M} are used as the transistor T_{BLK}. According to such a configuration, it is possible to implement a semiconductor storage device that facilitates high density integration in the X direction by appropriately dividing and arranging the circuit of the transistor T_{BLK} in the Z direction.

For the reason in the manufacturing process, the transistor Tr in the chip C_{M} may have an operating speed slower than the transistor Tr in the chip C_{P}. Here, the transistor T_{BLK} has a need for a high-speed operation, which is lower than the input/output control circuit I/O (FIG. 4), for example. Thus, when the transistor Tr is used as the transistor T_{BLK}, it is considered that, even though the transistor Tr in the chip C_{M} and the transistor Tr in the chip C_{P} are used together, the influence on the operating speed of the semiconductor storage device is small. Thus, in the first embodiment, it is possible to achieve high density integration of a semiconductor storage device while suppressing the influence on the operating speed.

For the reason in the manufacturing process, the transistor Tr in the chip C_{M} may have a more difficulty in high density integration than the transistor Tr in the chip C_{P}. Therefore, in the first embodiment, the width X_{TAM} (FIG. 21) of the active region 100A constituting the transistor T_{BLK} in the chip C_{M}, in the X direction, is set to be larger than the width X_{TAP} (FIG. 22) of the active region 150A constituting the transistor T_{BLK} in the chip C_{P}, in the X direction. As a result, in the first embodiment, it is possible to achieve high density integration of a semiconductor storage device while suppressing a decrease in yield.

### Second Embodiment

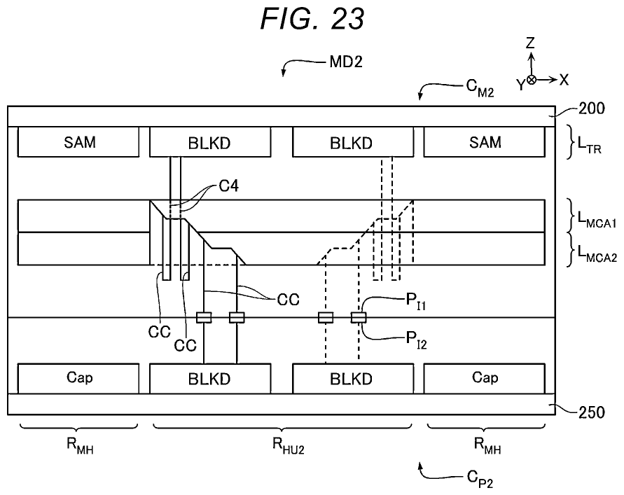

Next, a semiconductor storage device according to a second embodiment will be described with reference to FIG. 23. FIG. 23 is a cross-sectional view schematically illustrating a semiconductor storage device according to the second embodiment.

For example, as illustrated in FIG. 17 and the like, the memory die MD according to the first embodiment includes the chip C_{M} including the memory cell array MCA and the chip C_{P} bonded to the chip C_{M}. The peripheral circuit PC is mainly configured with the transistors Tr included in the chip C_{P}, and the transistors Tr included in the memory cell array MCA are used only as some of the plurality of transistors T_{BLK}. On the other hand, for example, as illustrated in FIG. 23, a memory die MD2 according to the second embodiment includes a chip C_{M2} including a memory cell array MCA and a chip C_{P2} bonded to the chip C_{M2}.

The chip C_{M2} is basically configured in a manner similar to the chip C_{M}. However, the chip C_{M2} includes a semiconductor substrate 200 instead of the semiconductor substrate 100. The semiconductor substrate 200 is basically configured in a manner similar to the semiconductor substrate 100. However, among a plurality of transistors Tr provided on the front surface of the semiconductor substrate 200, the transistors provided in a memory hole region R_{MH} function as a portion of the sense amplifier module SAM or the cache memory C_{M} (FIG. 4).

The chip C_{P2} is basically configured in a manner similar to the chip C_{P}. However, the chip C_{P2} includes a semiconductor substrate 250 instead of the semiconductor substrate 150. The semiconductor substrate 250 is basically configured in a manner similar to the semiconductor substrate 150. However, the above-described capacitor Cap is provided in a region other than the second hookup region R_{HU2} on the surface of the semiconductor substrate 250 of the chip C_{P2}.

### Third Embodiment

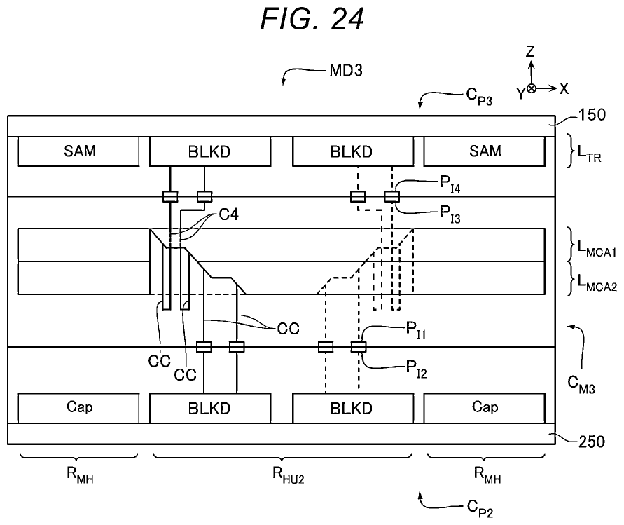

Next, a semiconductor storage device according to a third embodiment will be described with reference to FIG. 24. FIG. 24 is a cross-sectional view schematically illustrating a semiconductor storage device according to the third embodiment.

For example, as illustrated in FIG. 17 and the like, the memory die MD according to the first embodiment includes the chip C_{M} including the memory cell array MCA, and the transistors Tr are provided in the chip C_{M}. Similarly, as described with reference to FIG. 23, for example, the memory die MD2 according to the second embodiment includes the chip C_{M2} including the memory cell array MCA, and the transistors Tr are provided in the chip C_{M2}. On the other hand, for example, as illustrated in FIG. 24, a memory die MD3 according to the third embodiment includes a chip C_{M3} including a memory cell array MCA, a chip C_{P2} bonded to the front surface (lower surface) of the chip C_{M3}, and a chip C_{P3} bonded to the rear surface (upper surface) of the chip C_{M3}.

The chip C_{M3} is basically configured in a manner similar to the chip C_{M}. However, the chip C_{M3} does not include the semiconductor substrate 100 and the transistor layer L_{TR}. A plurality of third bonding electrodes P_{I3} are provided on the rear surface (upper surface) of the chip C_{M3}. The plurality of third bonding electrodes P_{I3} are basically configured in a manner similar to the plurality of first bonding electrodes P_{I1}.

The chip C_{P3} is basically configured in a manner similar to the chip C_{P}. However, a plurality of fourth bonding electrodes PI4 are provided on the front surface (lower surface) of the chip C_{P3} instead of the plurality of second bonding electrodes P_{I2}. The plurality of fourth bonding electrodes PI4 are basically configured in a manner similar to the plurality of second bonding electrodes P_{I2}. However, the plurality of fourth bonding electrodes PI4 are connected not to the plurality of first bonding electrodes P_{I1}, but to the plurality of third bonding electrodes P_{I3}. Although not illustrated, a bonding pad electrode P_{X} is provided on the rear surface (upper surface) of the chip C_{P3}.

### Fourth Embodiment

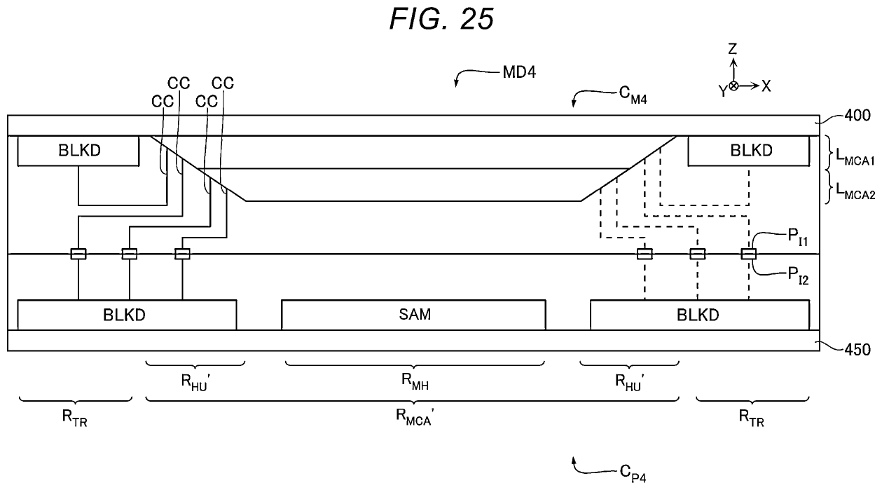

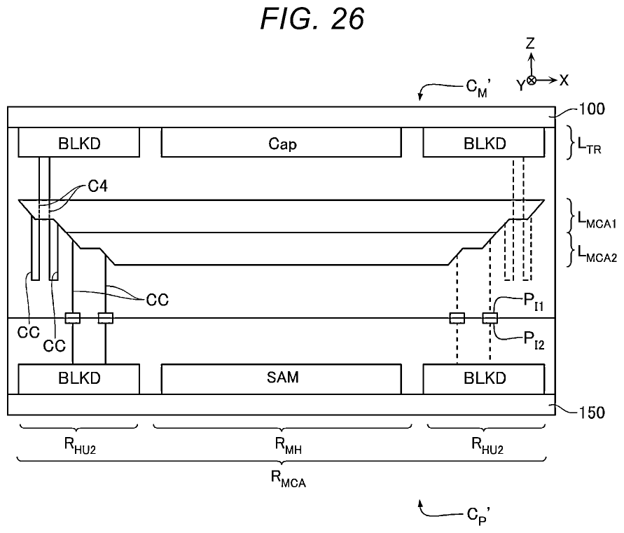

Next, a semiconductor storage device according to a fourth embodiment will be described with reference to FIG. 25. FIG. 25 is a cross-sectional view schematically illustrating a semiconductor storage device according to the fourth embodiment.

For example, as illustrated in FIG. 17 and the like, the memory die MD according to the first embodiment includes the chip C_{M} and the chip C_{P}. The chip C_{M} includes the memory cell array layers L_{MCA1} and L_{MCA2}, and the transistor layer L_{TR}. The transistor layer L_{TR} is spaced from the memory cell array layers L_{MCA1} and L_{MCA2} in the Z direction. On the other hand, for example, as illustrated in FIG. 25, a memory die MD4 according to the fourth embodiment includes a chip C_{M4} including a memory cell array MCA and a chip C_{P4} bonded to the chip C_{M4}.

The chip C_{M4} is basically configured in a manner similar to the chip C_{M}. However, the chip C_{M4} includes a semiconductor substrate 400 instead of the semiconductor substrate 100. The chip C_{M4} does not include the transistor layer L_{TR}. The semiconductor substrate 400 is basically configured in a manner similar to the semiconductor substrate 100. However, a memory cell array region R_{MCA}′ is provided in the semiconductor substrate 400 instead of the memory cell array region R_{MCA}. The memory cell array region R_{MCA}′ has a memory hole region R_{MH}′ and two hookup regions R_{HU}′ adjacent to the memory hole region R_{MH}′. A transistor region RTR is provided at a position adjacent to the memory cell array region R_{MCA}′ in the X direction.

The configuration of the memory hole region R_{MH}′ of the memory cell array layers L_{MCA1} and L_{MCA2} is basically similar to the configuration of the memory hole region R_{MH} of the memory cell array layers L_{MCA1} and L_{MCA2} in the chip C_{M}. However, a conductive layer 112 is not provided in the memory hole region R_{MH}′. The upper end of the semiconductor pillar 120 in the memory hole region R_{MH} is connected not to the conductive layer 112 but to the semiconductor substrate 400.

The hookup region R_{HU}′ is basically configured in a manner similar to the first hookup region R_{HU1} and the second hookup region R_{HU2}. However, a contact connection small-region r_{C4T} is not provided in the hookup region R_{HU}′.

In the transistor region R_{TR}, a plurality of transistors Tr are provided on the front surface (lower surface) of the semiconductor substrate 400. The plurality of transistors Tr constitute a portion of the block decoder BLK_{D}. The plurality of transistors Tr are connected to the components in the memory cell array layer L_{MCA1} Via contacts CC or the like.

The chip C_{P4} is basically configured in a manner similar to the chip C_{P}. However, the chip C_{P4} includes a semiconductor substrate 450 instead of the semiconductor substrate 150. The semiconductor substrate 450 is basically configured in a manner similar to the semiconductor substrate 150. However, among the plurality of transistors Tr provided on the front surface (upper surface) of the semiconductor substrate 450, the transistors Tr provided in the hookup region R_{HU}′ and the transistor region RTR constitute a portion of the block decoder BLK_{D}. The plurality of transistors Tr are connected to the components in the memory cell array layers L_{MCA1} and L_{MCA2} via the contacts CC, the first bonding electrode P_{I1}, the second bonding electrode P_{I2}, and the like.

[Other Embodiments] Hitherto, the semiconductor storage device according to the first to fourth embodiments has been described. However, the semiconductor storage device to the above embodiments are merely examples, and specific configurations, operations, and the like can be appropriately adjusted.

For example, as illustrated in FIGS. 17, 23, and 24, in the semiconductor storage device according to the first to third embodiments, the two memory hole regions R_{MH} arranged in the X direction are provided in the memory cell array region R_{MCA}, and the second hookup region R_{HU2} is provided between the two memory hole regions R_{MH}. On the other hand, for example, a chip C_{M}′ and a chip C_{P}′ illustrated in FIG. 26 are basically configured in a manner similar to the chip C_{M} and the chip C_{P} according to the first embodiment. However, in the chip C_{M}′, two second hookup regions R_{HU2} arranged in the X direction are provided in a memory cell array region R_{MCA}, and a memory hole region R_{MH} is provided between the two second hookup regions R_{HU2}. Among a plurality of transistors Tr provided on the front surfaces of the chip C_{M}′ and the chip C_{P}′, the transistors Tr provided in the second hookup region R_{HU2} function as a portion of the block decoder BLK_{D}.

Such a configuration can also be applied to the semiconductor storage device according to the second or third embodiment.

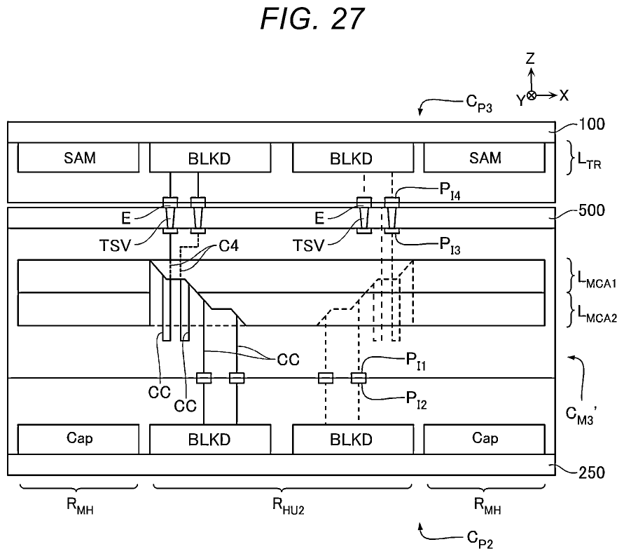

For example, as illustrated in FIG. 24, in the semiconductor storage device according to the third embodiment, the chip C_{M3} does not include the semiconductor substrate. The plurality of third bonding electrodes P_{I3} are provided on the rear surface (upper surface) of the chip C_{M3}. On the other hand, for example, a chip C_{M3}′ illustrated in FIG. 27 includes a semiconductor substrate 500. The chip C_{M3}′ includes a plurality of through-electrode TSVs penetrating the semiconductor substrate 500 and electrodes E provided at the upper ends of the plurality of through-electrodes TSV. In such a configuration, some conductive layers 110 in the memory cell array layers L_{MCA1} and L_{MCA2} are connected to the transistors Tr included in the block decoder BLK_{D} in the chip C_{P3} via the contacts CC, the contacts C4, the third bonding electrodes P_{I3}, the through-electrodes TSV, the electrodes E, and the fourth bonding electrodes PI4.

In the above example, among a plurality of conductive layers 110 provided in the memory cell array layers L_{MCA1} and L_{MCA2}, the conductive layer 110 connected to the transistor Tr in the chip C_{M}, C_{M2}, C_{M4}, or C_{M}′ (referred to as the “chip C_{M} or the like” below) and the conductive layer 110 connected to the transistor Tr in the chip C_{P}, C_{P2}, C_{P3}, C_{P4}, or C_{P}′ (referred to as the “chip C_{P} or the like” below) can be appropriate adjusted.

For example, a plurality of conductive layers 110 included in one of the memory cell array layers L_{MCA1} and L_{MCA2} are connected to the transistors Tr in the chip C_{M} or the like, and a plurality of conductive layers 110 included in the other memory cell array layer may be connected to the transistors Tr in the chip C_{P} or the like.

For example, the number of conductive layers 110 connected to the transistors Tr in the chip C_{P} or the like may be greater than the number of conductive layers 110 connected to the transistors Tr in the chip C_{M} or the like. As described above, for the reason in the manufacturing process, the transistor Tr in the chip C_{M} may have a more difficulty in high density integration than the transistor Tr in the chip C_{P}. Thus, it is possible to reduce the circuit area by setting the number of conductive layers 110 connected to the transistors Tr in the chip C_{P} or the like to be greater than the number of conductive layers 110 connected to the transistors Tr in the chip C_{M} or the like.

Further, for example, the even-numbered or odd-numbered conductive layers 110 counting from the top may be connected to the transistors Tr in the chip C_{P} or the like, and the odd-numbered or even-numbered conductive layers 110 counting from the top may be connected to the transistors Tr in the chip C_{M} or the like. For example, the conductive layers 110 included in the even-numbered or odd-numbered memory blocks BLK counting from one side (for example, negative side in the Y direction. see FIG. 12) in the Y direction may be connected to the transistors Tr in the chip C_{P} or the like, and the conductive layers 110 included in the odd-numbered or even-numbered memory blocks BLK counting from the one side in the Y direction may be connected to the transistors Tr in the chip C_{M} or the like. For example, the conductive layers 110 included in one of the memory blocks BLKa and BLKf described with reference to FIG. 12 and the like may be connected to the transistors Tr in the chip C_{P} or the like, and the conductive layers 110 included in the other of the memory blocks BLKa and BLKf may be connected to the transistors Tr in the chip C_{M} or the like.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a first chip including a first semiconductor substrate, a memory cell array including a plurality of memory cells, and a plurality of first and second word lines electrically connected to gates of the memory cells, a first active region being formed in the first semiconductor substrate, a plurality of first transistors being formed with the first active region, the plurality of first transistors being turned on and off to control voltages applied to the first word lines; and
a second chip bonded to the first chip and including a second semiconductor substrate, a second active region being formed in the second semiconductor substrate, a plurality of second transistors being g formed with the second active region, the plurality of second transistors being turned on and off to control voltages applied to the second word lines.

2. The semiconductor storage device according to claim 1, wherein a density of the second transistors inf the second semiconductor substrate is greater than a density of the first transistors in the first semiconductor substrate.

3. The semiconductor storage device according to claim 1, wherein
each of the plurality of first and second word lines extends in a first direction that is parallel to a surface of the first semiconductor substrate, and
a source and a drain of each of the first transistors are aligned in a second direction that is parallel to the surface of the first semiconductor substrate and orthogonal to the first direction.

4. The semiconductor storage device according to claim 3, wherein a source and a drain of each of the second transistors are aligned in the second direction.

5. The semiconductor storage device according to claim 4, wherein a width of each of the first transistors in the first direction is greater than a width of each of the second transistors in the first direction.

6. The semiconductor storage device according to claim 4, wherein a distance in the first direction between two adjacent first transistors that are closest to each other in the first direction is greater than a distance in the first direction between two adjacent second transistors that are closest to each other in the first direction.

7. The semiconductor storage device according to claim 4, wherein a length of each of the first transistors in the first direction is equal to a length of each of the second transistors in the first direction.

8. The semiconductor storage device according to claim 1, wherein the first chip includes a hookup region into which each of the plurality of first and second word lines extends in a first direction that is parallel to a surface of the first semiconductor substrate and in which no memory cell is provided, wherein the first active region is formed in the first semiconductor substrate in the first hookup region.

9. The semiconductor storage device according to claim 8, wherein the second active region is formed in the second semiconductor substrate in a region thereof that coincides with the hookup region of the first chip.

10. The semiconductor storage device according to claim 8, wherein
each of the first and second word lines that is closer to the first semiconductor substrate than a neighboring word line adjacent thereto extends farther into the hookup region than the neighboring word line so that a stair-shaped pattern is formed by the first and second word lines extending into the hookup region.

11. The semiconductor storage device according to claim 1, wherein the second chip includes no memory cell array.

12. The semiconductor storage device according to claim 1, wherein the plurality of first transistors and the plurality of second transistors are a part of a block decoder circuit.

13. The semiconductor storage device according to claim 1, wherein an operating speed of the first transistors is slower than an operating speed of the second transistors.

14. The semiconductor storage device according to claim 1, wherein
the memory cell array includes a first memory cell array layer and a second memory cell array layer, the first memory cell array layer being provided between the first semiconductor substrate and the second memory cell array layer, and
the plurality of first word lines are connected to gates of memory cells in the first memory cell array layer, and the plurality of second word lines are connected to gates of memory cells in the second memory cell array layer.
